(19) United States
(12) Patent Application Publication
(10) Pub. No.: US 2023/0072083 A1
(43) Pub. Date: Mar. 9, 2023

(54) SYSTEM AND METHOD FOR SCREENING OF PROTEIN-LIGAND INTERACTIONS USING PARA-HYDROGEN POLARIZATION AND NMR

(71) Applicant: THE TEXAS A&M UNIVERSITY SYSTEM, College Station, TX (US)

(72) Inventors: Christian HILTY, College Station, TX (US); Ratnamala MANDAL, College Station, TX (US); Pierce PHAM, College Station, TX (US)

(21) Appl. No.: 17/892,578

(22) Filed: Aug. 22, 2022

Related U.S. Application Data
(60) Provisional application No. 63/235,276, filed on Aug. 20, 2021.

(51) Int. Cl. G01N 24/08; G01R 33/28; G01R 33/465

(52) U.S. Cl. CPC G01N 24/08; G01R 33/282; G01R 33/465

(57) ABSTRACT

The present disclosure provides methods for measuring interactions between a ligand and a protein, comprising hyperpolarizing a ligand in a solvent using para-hydrogen to form a first solution; transferring the first solution to a detector; mixing the first solution with a protein solution, the protein solution having one or more ligands of interest therein; and determining interactions of the hyperpolarized ligand with the one or more ligands of interest by observing a change in an NMR signal of the hyperpolarized ligand. The ligand can include one or more sites for hyperpolarization by parahydrogen, and one or more binding sites for interaction with the protein.

### CROSS-REFERENCE TO RELATED APPLICATIONS

This application claims the benefit under 35 U.S.C. § 119(e) of U.S. Provisional Application Ser. No. 63/235,276, filed on Aug. 20, 2021, the entire disclosure of which is incorporated herein by reference.

### BACKGROUND AND SUMMARY OF THE INVENTION

In 2019, the U.S. pharmaceutical industry invested 83 billion in research and development and in 2021 alone, 50 novel drugs were approved by the Food and Drug Administration. Numerous new drug targets are discovered on an annual basis. As a result, a high level of drug development will undoubtedly become increasingly important.

Small organic molecules are the active ingredients in many pharmaceuticals. The molecules are designed to bind to and inhibit a receptor, enzyme or other protein targets in-vivo. However, the drug discovery process includes several bottlenecks. For instance, early in the discovery process, compounds that bind to a specific target must be identified. Typically, this analysis is done by experimentally verifying interactions for a large number of drug candidates. Biding detection can be achieved based on changes in a parameter detected by various methods, for instance by optical spectroscopy or nuclear magnetic resonance (NMR).

NMR methods of drug discovery can be accomplished by observing a property such as nuclear spin that is contained in the analyzed molecule without the requirement for including a synthetic label. Although NMR can be used for high-throughput screening to identify binding to the detection of binding affinity, localization to a binding pocket, or determination of binding pocket structure, a major disadvantage of NMR spectroscopy in this context is its low detection sensitivity. Accordingly, there exists a need for improved systems and methods that utilize NMR in the drug discovery process.

The present disclosure utilizes a hyperpolarization method to provide such improved systems and methods. As described herein, hyperpolarization increases nuclear spin alignment prior to data acquisition and can improve signals by several levels of magnitude.

As described herein, the systems and methods can utilize methods such as signal amplification by reversible exchange (SABRE) that use hydrogen (H₂) in the para-spin state to provide desired outcomes. Para-hydrogen derived hyperpolarization can be generated inexpensively and has previously not been widely applied for biological NMR or for characterization of ligand interactions.

The systems and methods provide by the present disclosure provides several benefits by using para-hydrogen. It alleviates an incompatibility of the needed polarization transfer catalyst with aqueous samples and proteins as well as other effects that result in low polarization for this application. Further, separating the generation of hyperpolarization for a ligand, and detecting the interaction with the protein, allows optimizing both steps separately. Using the described systems, the hyperpolarized ligand can be injected rapidly into a spectrometer for NMR detection. The detection can occur in one of two modalities, either using a high-field NMR spectrometer containing a superconducting magnet or a low-field NMR instrument that requires only a weak electromagnet.

Although high field NMR can provide higher detection sensitivity, the low-field NMR methods have important cost advantages over other screening methods. The projected cost of an apparatus encompassing low-field NMR detection, which includes sample preparation, injection and measurement, is less than 10% of a high-field NMR system.

Moreover, the methods of the present disclosure can be utilized in competitive binding assays as shown in the examples provided herewith.

Other objects, features and advantages of the present disclosure will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 shows a 400 MHz NMR spectra of 0.3 mM 1.5 mM 4-amidinopyridine with Ir(IMeMes) polarization transfer catalyst in d₄-methanol (a) non-hyperpolarized (“thermal”) and (b) SABRE after bubbling for 30 s in a 6.5 mT magnetic field at 294 K, followed by acquisition at 9.4 T. The structures of the 4-amidinopyridine, and of the pre-catalyst before activation, are inset.

FIG. 2 shows non-hyperpolarized and hyperpolarized spectra of 4-amidinopyridine at different ligand concentrations of 1.5 mM, 5 mM and 10 mM. The enhancements obtained were −87 and −34 for Hₐ and H_{b} at 1.5 mM concentration, −140 and −60 for Hₐ and H_{b} at 5 mM concentration and −230 and −110 for Hₐ and H_{b} at 10 mM concentration.

FIG. 3 shows an instrument for SABRE NMR measurements of ligand binding. The putative ligand interacts with para-hydrogen and polarization transfer catalyst at 6.5 mT. It is subsequently delivered to a sample loop. The ligand and protein samples are pushed by high-pressure syringe pumps through the Y-mixer, to a flow-cell in the NMR magnet, where the measurement takes place.

FIG. 4A shows hyperpolarized signals measured using a CPMG experiment. Selected spectra from individual spin-echoes of 7.2 mM 4-amidinopyridine with polarization transfer catalyst in 36% methanol in final sample. FIG. 4B shows signal decay and exponential fit of integrals are from FIG. 4A. FIG. 4C shows spectra from 6.8 mM 4-amidinopyridine, catalyst, and 3.9 mM chelating ligand 2,2′-bipyridine in 34% methanol in the final sample. FIG. 4D shows signal decay and exponential fit of integrals are from FIG. 4C. FIG. 4E shows spectra from 5.9 mM 4-amidinopyridine, catalyst, 3.0 mM 2,2′-bipyridine and 0.33 mM trypsin in 30% methanol in final sample. FIG. 4F shows signal decay and exponential fit of integrals are from FIG. 4E.

FIG. 5 shows R₂ rate determination of 8 mM 4-amidinopyridine without hyperpolarization in 50 mM aqueous sodium phosphate buffer. The filled symbols are for the free ligand and the open symbols for the ligand with trypsin. The rates of the free form are 0.38 s⁻¹ for Hₐ (●), 0.26 s⁻¹ for H_{b} (▪), and 0.32 s⁻¹ for both protons integrated together (♦). The rates of the bound forms are 1.35 s⁻¹ for Hₐ (0), 1.36 s⁻¹ for H_{b} (□), and 1.35 s⁻¹ for the both protons integrated together (0).

FIG. 6 shows R₂ relaxation rates of 4-amidinopyridine. The green bar is from a non-hyperpolarized experiment in the absence of polarization transfer catalyst. The gray bars are from 4-amidinopyridine hyperpolarized by SABRE. Errors are shown as standard deviations from three separate measurements taken from different samples (see Table 1).

FIG. 7A shows competitive binding experiment with samples prepared in 50 mM sodium phosphate buffer of 1 mM TFBC and 18 μM trypsin (◯), 1 mM TFBC, 400 μM 4-amidinopyridine and 18 μM trypsin (□), 1 mM TFBC, 400 μM benzamidine and 18 μM trypsin (⋄), and FIG. 7B shows competitive binding experiment with samples prepared in 50 mM sodium phosphate buffer of 1 mM TFBC and 18 μM trypsin (◯), 1 mM TFBC, 800 μM 4-amidinopyridine and 18 μM trypsin (□), 1 mM TFBC, 400 μM benzamidine and 18 μM trypsin (⋄).

FIG. 8A shows the structure of chelating ligand 2,2′-bipyridine (top) and trypsin ligand 4-amidinopyridine (bottom), and non-hyperpolarized spectrum of ligand 4-amidinopyridine and chelating ligand 2,2′-bipyridine with catalyst in d₄-methanol (right). FIG. 8B shows signal intensity from single-scan CPMG experiment in the absence of ligand 4-amidinopyridine but presence of 1.2 mM chelating ligand 2,2′-bipyridine FIG. 8C shows fit from region corresponding to ligands. FIG. 8D shows signal intensity from single-scan CPMG experiment in the presence of ligand 7.3 mM 4-amidinopyridine and 2.9 mM chelating ligand 2,2′-bipyridine. FIG. 8E shows fit from region corresponding to ligands.

FIG. 9A shows non-hyperpolarized 400 MHz NMR spectra of 10 mM 4-amidinopyridine with Ir(IMeMes) catalyst in methanol-d₄. FIG. 9B shows SABRE hyperpolarized spectra of 4-amidinopyridine acquired at 9.4 T (400 MHz) after 30 s bubbling at 6.5 mT field and manual transfer time of 4 s. FIG. 9C shows non-hyperpolarized 400 MHz NMR spectra of 10 mM 4-amidinopyridine with 2,2′-bipyridine and activated Ir(IMeMes) SABRE catalyst in methanol-d₄. FIG. 9D shows SABRE hyperpolarized spectra of 4-amidinopyridine in the presence of 2,2′-bipyridine acquired at 9.4 T after 30 s bubbling at 6.5 mT field and manual transfer time of 4 s.

FIG. 10A shows spectra from CPMG echoes of 134 μM 4-amidinopyridine in presence of polarization transfer catalyst and chelating ligand. FIG. 10B shows spectra from CPMG echoes of 134 μM 4-amidinopyridine in presence of polarization transfer catalyst and chelating ligand after water signal subtraction. The final methanol fraction in the sample is 8.9%. FIG. 10C shows integrated and fitted signals from FIG. 10B. FIG. 10D shows spectra of 125 μM 4-amidinopyridine and 7.2 μM trypsin in presence of catalyst and chelating ligand. FIG. 10E shows spectra of 125 μM 4-amidinopyridine and 7.2 μM trypsin in presence of catalyst and chelating ligand after water signal subtraction. The final methanol in the sample is 8.3%. FIG. 10F shows integrated and fitted signals from FIG. 10E. Where indicated, the reference water spectrum was subtracted after scaling to the maximum solvent signal intensity in each echo. All spectra are plotted at the same scale.

FIG. 11 shows para-hydrogen pressure dependence of signal enhancement of 4-amidinopyridine with Ir(IMeMes) SABRE catalyst in methanol-d₄. The SABRE hyperpolarization was carried out at 6.5 mT by bubbling para-enriched hydrogen gas into the sample for 30 s. The NMR spectra were measured at 9.4 T after a manual transfer time of 4 s. The most negative number represents the highest enhancement.

FIG. 12A shows change in absorbance vs. time for the hydrolysis of BAEE catalyzed by trypsin, when the reaction was in 0% methanol (0.25 mM BAEE with 0.64 μM trypsin in Tris buffer) (□), in 10% methanol (0.25 mM BAEE with 0.64 μM trypsin in 90% Tris buffer and 10% methanol) (⋄), and in 30% methanol (0.25 mM BAEE with 0.64 μM trypsin in 70% Tris buffer and 30% methanol) (0). FIG. 12B shows fit of absorbance vs. time for the first 15 s of the reaction is in 0% methanol. The equation from the fit is y=0.0024792 s⁻¹*x+0.67579. FIG. 12C shows fit of absorbance vs. time for the first 15 s of the reaction in 10% methanol and 90% Tris buffer. The equation from the fit is y=0.0038 s⁻¹*x+0.6717. FIG. 12D shows fit of absorbance vs. time for the first 15 s of the reaction is in 30% methanol and 70% Tris buffer. The equation for the fit is y=0.0035737 s⁻¹*x+0.66409.

FIG. 13A shows R₂ relaxation measurement of 160 μM 4-amidinopyridine in presence of 308 μM cheating ligand 2,2′-bipyridine and catalyst. FIG. 13B shows R₂ of 135 μM 4-amidinopyridine in presence of 243 μM cheating ligand 2,2′-bipyridine, catalyst and 12.6 μM trypsin. The fitted relaxation rates are 0.53 s⁻¹ and 1.89 s⁻¹ in the absence (FIG. 13A) and presence (FIG. 13B) of trypsin, respectively.

FIGS. 14A-14C show R₂ relaxation rate of various competing ligands measured in the presence of reporter ligand 4-amidinopyridine. The sample conditions in FIG. 14A are 150 μM benzylamine, 179 μM 4-amidinopyridine and 14.7 μM trypsin. The sample conditions in FIG. 14B are 136 μM benzamidine, 146 μM 4-amidinopyridine and 13 μM trypsin. The sample conditions in FIG. 14C are 7 μM leupeptin, 140 μM 4-amidinopyridine and 8.4 μM trypsin. The rates are 1.54 s⁻¹, 0.85 s⁻¹ and 0.59 s⁻¹, respectively, for FIG. 14A, FIG. 14B, and FIG. 14C.

FIG. 15A shows structure of the reporter ligand 4-amidinopyridine. FIG. 15B shows schematic representation of the flow-NMR setup for ligand-binding characterization using SABRE. FIG. 15C shows series of spectra corresponding to 3000 CPMG echoes (τ=1.7 ms) for the reporter ligand (144 μM 4-amidinopyridine) without water subtraction. FIG. 15D shows series of spectra from (FIG. 15C) after water subtraction. FIGS. 15E and 15F show first 10 spectra from (FIG. 15C) and (FIG. 15D) shown enlarged. The chemical shifts of reporter ligand (L) and water are indicated.

FIG. 16A shows the real part from the FID of a single CPMG echo of the SABRE-hyperpolarized reporter ligand (144 μM 4-amidinopyridine) at t=1.05 s. FIG. 16B shows exponential window function that is multiplied before Fourier transform. FIG. 16C shows spectrum obtained after Fourier transform of the echo from FIG. 16A without water subtraction. FIG. 16D shows the real part from the echo of a single CPMG echo of the reference water (experiment with no reporter ligand) signal at t=1.05 s. FIG. 16E shows exponential window function that is multiplied before Fourier transform. FIG. 16F shows a spectrum obtained after Fourier transform of the echo from FIG. 16D. FIG. 16G shows a spectrum of the ligand after subtraction of reference water signal in FIG. 16F from the spectrum in FIG. 16C.

FIG. 17A shows spectra of hyperpolarized reporter ligand 4-amidinopyridine after Fourier transformation of echoes and water subtraction, in the absence of trypsin. FIG. 17B shows Echo signal intensities from FIG. 17A with fit indicating a relaxation rate of 0.48 s⁻¹ (data set shown) for the free ligand. R₂ values from three separate measurements were 0.47±0.01 s⁻¹. FIG. 17C shows spectra of hyperpolarized 130 μM 4-amidinopyridine in the presence of 11.7 μM trypsin, obtained from CPMG echoes as in FIG. 17A. FIG. 17D shows fit of the data in FIG. 17C, indicating a relaxation rate of 1.89 s⁻¹ (data set shown; 1.86±0.13 s⁻¹ from three measurements) in the presence of trypsin.

FIG. 18A shows structures of competing ligands and R₂ relaxation rates from CPMG experiments for the reporter ligand 4-amidinopyridine measured in the presence of competing ligands 161 μM 4-amidinopyridine with 166 μM benzylamine, 14.7 μM trypsin and chelating agent 2,2′-bipyridine. FIG. 18B shows structures of competing ligands and R₂ relaxation rates from CPMG experiments for the reporter ligand 4-amidinopyridine measured in the presence of competing ligands 146 μM 4-amidinopyridine with 136 μM benzamidine, 13 μM trypsin and chelating agent 2,2′-bipyridine. FIG. 18C shows structures of competing ligands and R₂ relaxation rates from CPMG experiments for the reporter ligand 4-amidinopyridine measured in the presence of competing ligands 140 μM 4-amidinopyridine with 7 μM leupeptin, 8.4 μM trypsin and chelating agent 2,2′-bipyridine. The fitted relaxation rates in competition, R_{2,r}^{(c)}, are 1.52 s⁻¹, 0.85 s⁻¹ and 0.55 s⁻¹ for the data sets shown in FIG. 18A, FIG. 18B, and FIG. 18C, respectively (1.47±0.04 s⁻¹, 0.88±0.06 s⁻¹ and 0.58±0.05 s⁻¹, respectively, from three measurements).

FIG. 19A shows experimental data sets before water subtraction with free ligand. FIG. 19B shows experimental data sets before water subtraction with ligand in presence of trypsin. FIG. 19C shows experimental data sets before water subtraction with reference water signal used for subtraction.

FIG. 20 shows hyperpolarized spectra of 160 μM 4-amidinopyridine in presence of 161 μM benzylamine, 2,2′-bipyridine chelating agent and 14.7 μM trypsin. The same reference water signal as shown above has been subtracted.

FIG. 21 shows hyperpolarized spectra of 146 μM 4-amidinopyridine in presence of 136 μM benzamidine, 2,2′-bipyridine chelating agent and 11.6 μM trypsin. The same reference water signal as shown above has been subtracted.

FIG. 22 shows hyperpolarized spectra of 144 μM 4-amidinopyridine in presence of 7.7 μM leupeptin, 2,2′-bipyridine chelating agent and 11.0 μM trypsin. The same reference water signal as shown above has been subtracted.

FIG. 23 shows titration of 100 μM trypsin (sodium phosphate buffer, pH=7.6) with 4-amidinopyridine ligand concentrations [R]₀ from 0.5 mM to 3.0 mM. The R_{2,obs} were determined from non-hyperpolarized CPMG experiments. The K_{D,r} obtained from the data set shown is 200 μM. The K_{D,r} values obtained from two other titration experiment are 157 and 98 μM respectively.

FIG. 24A shows the calculated relative fraction of the bound reporter between the competition and non-competition experiments, f=p_{b,r}^{(c)}/p_{b,r}^{(nc)}, plotted as a function of competitor concentration [C]₀ and dissociation constant K_{D,c} of the competing ligand of interest. For the calculation, a total concentration [P]₀=11 μM of trypsin, =145 μM of the reporter ligand, and K_{D,r}=152 μM were used. The experimental conditions are indicated for benzylamine (“1”, [C]₀=145±17 μM, K_{D,c}=200±70 μM), benzamidine (“2”, [C]₀=136±17 μM, K_{D,c}=28±7 μM), and leupeptin (“3”, [C]₀=7.2±0.8 μM, K_{D,c}=0.27±0.13 μM). The f values in the range of 0.2-0.8 are enclosed by dash-dotted curves. FIG. 24B shows horizontal cross-sections extracted from (a) at the K_{D,c} values for the three ligands.

FIG. 25 shows the calculated relative fraction of the bound reporter comparing the competition and non-competition experiments, f=p_{b,r}^{(c)}/p_{b,r}^{(nc)}, plotted as a function of the concentration [C]₀ and K_{D,c} of the competing ligand. The calculation is based on equations 1.2-1.8. The dissociation constant of the reporter ligand (K_{D,r}) is fixed at 152 μM. Three initial protein concentrations [P]₀ are set at 11, 1.1, and 0.11 μM, and three initial reporter concentrations [R]₀ are set at 145, 14.5, and 1.45 μM. The f values in the range of 0.2-0.8, corresponding to partial displacement, are enclosed between dash-dotted curves.

FIGS. 26A-26B demonstrate low-field NMR measurements of SABRE hyperpolarized ligand 4-amidinopyridine. FIG. 26A shows Fourier transformed signals from echoes acquired in a CPMG experiment of the hyperpolarized 4-amidinopyridine, which are arranged consecutively in accordance with the time at which they were measured. At the low field, chemical shifts are collapsed, such that a single signal is observed from each echo. FIG. 26B shows the corresponding relaxation trace comprising the echo signal intensities and a fit to a single exponential function. The observed relaxation rate in this example is R_{2=0.44} s⁻¹. The 4-amidinopyridine was hyperpolarized in a magnetic field of 6.5 mT at a concentration of 10 mM, with 1 mM chloro(1,5-cyclooctadiene)[4,5-dimethyl-1,3-bis(2,4,6-trimethylphenyl)imidazol-2-ylidene] iridium and 10 mM methyl phenyl sulfoxide in methanol, by bubbling ˜95% para-enriched hydrogen at 120 psi at 45° C. for 15 s. The sample was injected into the low-field NMR instrument via a 0.5 mL sample loop, and diluted with aqueous buffer. NMR measurement occurred at a field strength of 0.67 mT at a final concentration of 4-amidinopyridine of 234 μM.

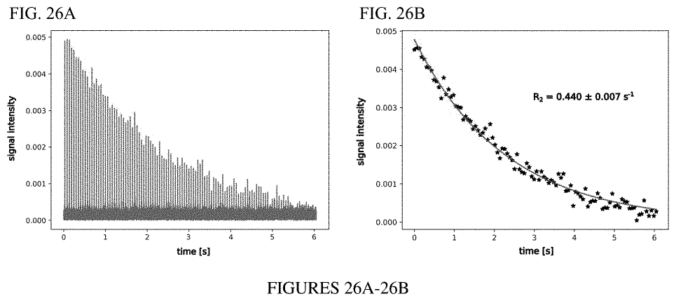

FIG. 27 shows a liquid driven injection system with an additional automatic syringe pump that dilutes SABRE sample prior to be injected to a sample loop, providing for the ability to measure the interaction at a lower concentration with improved polarization. FIGS. 28-31 are indicative of data generated with such a system.

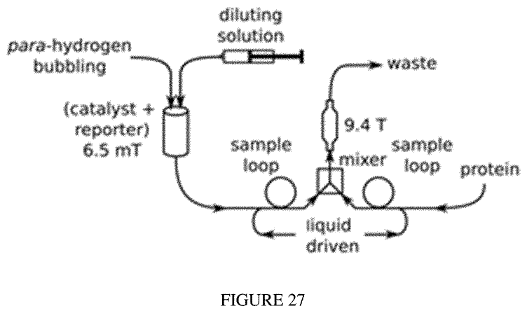

FIG. 28 depicts spectra of 4-amidinopyridine in non-hyperpolarized (thermal) and SABRE-hyperpolarized conditions, top and bottom traces respectively. A SABRE sample comprises 1 mM of (^{Me}IMes)Ir(COD)Cl precatalyst, 10 mM 4-amidinopyridine, and 10 mM methyl phenyl sulfoxide (as a coligand) in deuterated methanol-d4. SABRE experiments are conducted with a flow rate of 0.2 slpm of 120 psi para-hydrogen (˜95% enrichment) at 45° C. and 6.5 mT in 15 seconds.

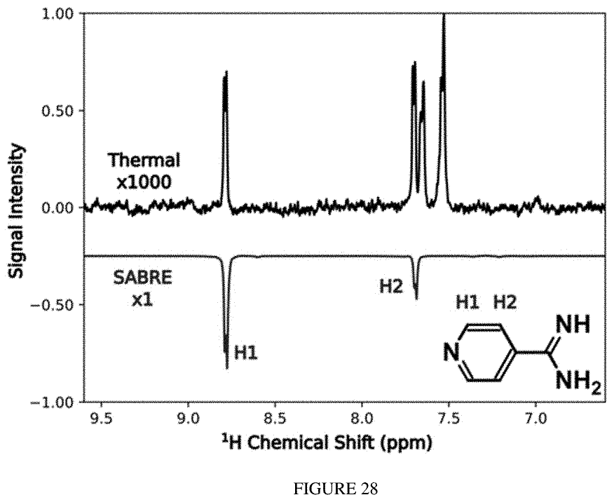

FIG. 29 displays spectrum of 4.5 μM 4-amidinopyridine in an NMR flow cell after being injected by the liquid injector system of FIG. 27.

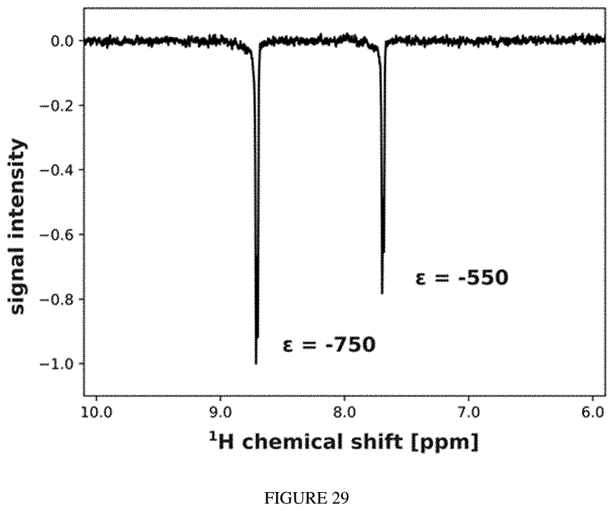

FIG. 30 shows R₂ relaxation rate of 15.6 μM 4-amidinopyridine that is determined from a CPMG pulse train at 9.4 T.

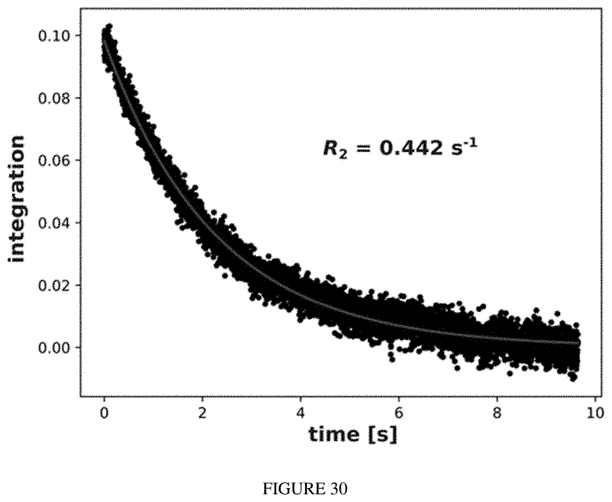

FIG. 31 shows R₂ relaxation rate of 15.0 μM 4-amidinopyridine with 1.7 μM trypsin that is determined from a CPMG pulse train at 9.4 T.

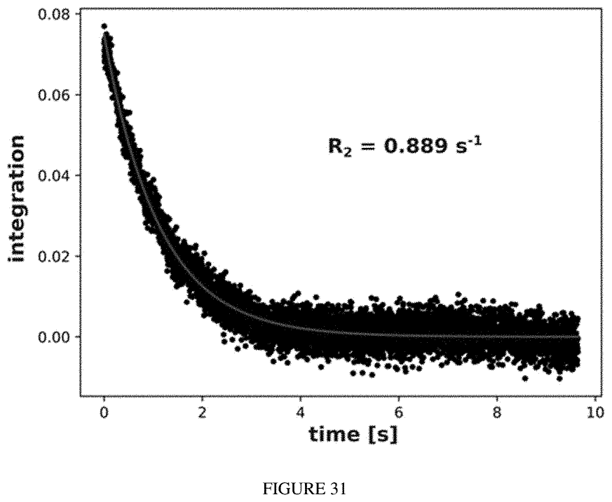

### DETAILED DESCRIPTION

Various embodiments of the invention are described herein as follows. In an illustrative aspect, a method for measuring interactions between a ligand and a protein is provided. The method comprises the steps of hyperpolarizing a ligand in a solvent using para-hydrogen to form a first solution; transferring the first solution to a detector; mixing the first solution with a protein solution, the protein solution having one or more ligands of interest therein; and determining interactions of the hyperpolarized ligand with the one or more ligands of interest by observing a change in an NMR signal of the hyperpolarized ligand, wherein the ligand includes one or more sites for hyperpolarization by parahydrogen, and one or more binding sites for interaction with the protein.

In an embodiment, the ligand is hyperpolarized by signal amplification by reversible exchange (SABRE) to transfer nuclear spin polarization from para-hydrogen. SABRE is generally known in the art to the skilled artisan. In an embodiment, the nuclear spin polarization is transferred from para-hydrogen to molecules of interest.

In an embodiment, the ligand is hyperpolarized by a hydrogenation catalyst where the ligand reacts with parahydrogen. In an embodiment, the nuclear spin polarization is transferred from para-hydrogen to molecules of interest.

In an embodiment, the one or more binding sites of the hyperpolarized ligand bind weakly to the protein. In an embodiment, the ligands of interest are comprised in a library of potential candidate ligands for the protein. In an embodiment, the hyperpolarized ligand is the ligand of interest.

In an embodiment, determining interactions of the hyperpolarized ligand is performed in the absence of superconducting magnets. In an embodiment, determining interactions of the hyperpolarized ligand is performed in the absence of high field NMR. In an embodiment, a frequency of the NMR signal is less than about 1 Tesla.

In an embodiment, hyperpolarization of the ligand in the solvent is performed in water-based solvent. In an embodiment, hyperpolarization of the ligand in the solvent is performed in an organic solvent. In an embodiment, the hyperpolarization of the ligand further comprises using a reversible transfer catalyst in the organic solvent. In an embodiment, the hyperpolarization of the ligand further comprises using a hydrogenative catalyst for producing parahydrogen derived polarization. In an embodiment, the organic solvent further comprises one or more of methanol, ethanol, chloroform, dichloromethane, or any combination thereof.

In an embodiment, the protein solution is aqueous. In an embodiment, the method further comprises diluting the solvent to minimize a concentration of organic solvent therein. In an embodiment, the solvent is diluted at a ratio approximately in a range of about 1:10 to about 1:100. In an embodiment, the ligand comprises 4-amidinopyridine, 2,4-diaininopyrimidine, trimethoprim, or any combination thereof.

In an embodiment, the step of transferring the first solution to the detector further comprises injecting the hyperpolarized molecule into an NMR spectrometer. In an embodiment, the injecting is automated.

In an embodiment, the step of observing a change in the NMR signal of the hyperpolarized ligand further comprises measuring a change in spin rate of the hydrogens in the ligand. In an embodiment, observing the change in the NMR signal of the hyperpolarized ligand further comprises one or more of observing a spin-spin (R₂) relaxation of one or more hyperpolarized ligand spins or detection of a change in the binding of the hyperpolarized ligand to identify binding of the ligand of interest. In an embodiment, the change in the binding of the hyperpolarized ligand is identified from one or more of spin-lattice (R₁) relaxation rate, cross-relaxation rate, chemical shift, and molecular self-diffusion measured by pulsed field gradient NMR.

In an embodiment, the method further comprises calculating a binding affinity of the ligand of interest. In an embodiment, the method further comprises optimizing the magnetic field for detection sensitivity based on the hyperpolarized ligand. In an embodiment, the ligand is not modified following hyperpolarization.

In an embodiment, the method further comprises optimizing a mixing ratio to lower a volume of the first solution that is mixed with the protein solution while increasing the ligand concentration during hyperpolarization. In an embodiment, the method further comprises adjusting a concentration of one or more of a second ligand, a polarization catalyst, an exchange rate in the polarization process, a reaction rate in the polarization process, or any combination thereof.

In an embodiment, the hyperpolarization process further comprises bubbling a para-enriched hydrogen gas into the organic or other solvent. In an embodiment, the para-enriched hydrogen gas is delivered at a pressure of about 10 bar.

In an illustrative aspect, another method for measuring interactions between a ligand and a protein is provided. The method comprises the steps of hyperpolarizing a ligand in a solvent using para-hydrogen to form a first solution; transferring the first solution to a detector; mixing the first solution with a protein solution, the protein solution optionally having one or more ligands of interest therein; and determining interactions of the hyperpolarized ligand with the protein and optionally with one or more ligands of interest by observing a change in an NMR signal of the hyperpolarized ligand, wherein the ligand includes one or more binding sites for a polarization transfer catalyst and interaction with the one or more ligands of interest. According to this described method, a hyperpolarized ligand itself is capable of being the ligand of interest.

In an illustrative aspect, a method for creating a polarizable ligand is provided. The method comprises the steps of introducing a signal amplification by reversible exchange (SABRE) catalyst or a reaction site for a hydrogenative polarization transfer catalyst to a first ligand in a solvent to produce hyperpolarization of the first ligand; and mixing hyperpolarized first ligand with a protein solution having a second ligand admixed therein to form a solution, such that a signal of the first ligand in the presence of the second ligand differs from a signal of the first ligand in the absence of the second ligand. Importantly, this described method can be utilized for means of competitive binding according to the present disclosure.

In an embodiment, the solvent is an organic solvent. In an embodiment, the solvent is a water-based solvent. In an embodiment, the step of introducing the catalyst to the first ligand in a solvent to produce hyperpolarization of the first ligand forms a hyperpolarized first ligand solution. In an embodiment, the method further comprises injecting the solution into an NMR spectrometer. In an embodiment, the injection is automated.

In an embodiment, the signal amplification by reversible exchange (SABRE) transfer catalyst comprises [Ir(IMeMes)(COD)]Cl, [Ir(^{Me}IMes)(COD)]Cl, and [Ir(κC,N—NHC)(COD)]BPh₄ (IMeMes=1-(2,4,6-trimethylphenyl)-3-methylimidazol-2-ylidene, COD=1,5-cyclooctadiene, ^{Me}IMes=1,3-bis(2,4,6-trimethylphenyl)imidazol-2-ylidene, and κC,N—NHC=1-(2,4,6-trimethylphenyl)-3-(1-pyrazolylmethyl)imidazol-2-ylidene, 1-(2,4,6-trimethylphenyl)-3-(2-pyridylmethyl)imidazol-2-ylidene, 1-(2,6-diisopropylphenyl)-3-(1-pyrazolylmethyl)imidazol-2-ylidene, 1-(2,6-diisopropylphenyl)-3-(2-pyridylmethyl)imidazol-2-ylidene, BPh₄=tetraphenylborate), or any combination thereof.

In an embodiment, the method further comprises adjusting a concentration of one or more of the second ligand, the polarization transfer catalyst, or an exchange rate in the catalyst-ligand complex.

In an embodiment, introducing the transfer catalyst further comprises bubbling a para-enriched hydrogen gas into the organic solvent. In an embodiment, the para-enriched hydrogen gas is delivered at a pressure of about 10 bar.

In an embodiment, a concentration of the second ligand in the protein solution is approximately in a range of about 10 micromolars to about 500 micromolars. In an embodiment, the method further comprises adjusting a concentration of the second ligand in the protein solution in response to expected binding affinities.

In an illustrative aspect, method for creating a polarizable ligand is provided. The method comprises the steps of introducing a binding site for a non-hydrogenative polarization transfer catalyst or a reaction site for a hydrogenative polarization catalyst, as a modification to a ligand of the protein, wherein the modification provides formation of a catalyst-ligand complex or the causation of a hydrogenation reaction to hyperpolarize the ligand.

In an embodiment, the binding site for a non-hydrogenative polarization transfer catalyst comprises use of a SABRE transfer catalyst. In an embodiment, the modification of the ligand results in a weak binding affinity, where the ligand is in fast exchange with its protein bound form. In an embodiment, the hyperpolarizable ligand has a dissociation constant with the protein between 10 micromolar and 500 micromolar. In an embodiment, the hyperpolarizable ligand binds competitively to the protein with one or more ligands of interest.

In an embodiment, the SABRE transfer catalyst comprises [Ir(IMeMes)(COD)]Cl, [Ir(^{Me}IMes)(COD)]Cl, and [Ir(κC,N—NHC)(COD)]BPh₄ (IMeMes=1-(2,4,6-trimethylphenyl)-3-methylimidazol-2-ylidene, COD=1,5-cyclooctadiene, ^{Me}IMes=1,3-bis(2,4,6-trimethylphenyl)imidazol-2-ylidene, and κC,N—NHC=1-(2,4,6-trimethylphenyl)-3-(1-pyrazolylmethyl)imidazol-2-ylidene, 1-(2,4,6-trimethylphenyl)-3-(2-pyridylmethyl)imidazol-2-ylidene, 1-(2,6-diisopropylphenyl)-3-(1-pyrazolylmethyl)imidazol-2-ylidene, diisopropylphenyl)-3-(2-pyridylmethyl)imidazol-2-ylidene, BPh₄=tetraphenylborate), or any combination thereof.

A system comprising means for the various methods and/or method steps according to the present disclosure is also provided.

The following numbered embodiments are contemplated and are non-limiting:

1. A method for measuring interactions between a ligand and a protein, the method comprising:

hyperpolarizing a ligand in a solvent using para-hydrogen to form a first solution;

transferring the first solution to a detector;

mixing the first solution with a protein solution, the protein solution having one or more ligands of interest therein; and

determining interactions of the hyperpolarized ligand with the one or more ligands of interest by observing a change in an NMR signal of the hyperpolarized ligand,

wherein the ligand includes one or more sites for hyperpolarization by parahydrogen, and one or more binding sites for interaction with the protein.

2. The method of clause 1, any other suitable clause, or any combination of suitable clauses, wherein the ligand is hyperpolarized by signal amplification by reversible exchange (SABRE) to transfer nuclear spin polarization from para-hydrogen.
3. The method of clause 1, any other suitable clause, or any combination of suitable clauses, wherein the nuclear spin polarization is transferred from para-hydrogen to molecules of interest.
4. The method of clause 1, any other suitable clause, or any combination of suitable clauses, wherein the ligand is hyperpolarized by a hydrogenation catalyst where the ligand reacts with parahydrogen.
5. The method of clause 1, any other suitable clause, or any combination of suitable clauses, wherein the nuclear spin polarization is transferred from para-hydrogen to molecules of interest.
6. The method of clause 1, any other suitable clause, or any combination of suitable clauses, wherein the one or more binding sites of the hyperpolarized ligand bind weakly to the protein.
7. The method of clause 1, any other suitable clause, or any combination of suitable clauses, wherein the ligands of interest are comprised in a library of potential candidate ligands for the protein.
8. The method of clause 1, any other suitable clause, or any combination of suitable clauses, wherein the hyperpolarized ligand is the ligand of interest.
9. The method of clause 1, any other suitable clause, or any combination of suitable clauses, wherein determining interactions of the hyperpolarized ligand is performed in the absence of superconducting magnets.
10. The method of clause 1, any other suitable clause, or any combination of suitable clauses, wherein determining interactions of the hyperpolarized ligand is performed in the absence of high field NMR.
11. The method of clause 1, any other suitable clause, or any combination of suitable clauses, wherein a frequency of the NMR signal is less than about 1 Tesla.
12. The method of clause 1, any other suitable clause, or any combination of suitable clauses, wherein hyperpolarization of the ligand in the solvent is performed in water-based solvent.
13. The method of clause 1, any other suitable clause, or any combination of suitable clauses, wherein hyperpolarization of the ligand in the solvent is performed in an organic solvent.
14. The method of clause 1, any other suitable clause, or any combination of suitable clauses, wherein the hyperpolarization of the ligand further comprises using a reversible transfer catalyst in the organic solvent.
15. The method of clause 1, any other suitable clause, or any combination of suitable clauses, wherein the hyperpolarization of the ligand further comprises using a hydrogenative catalyst for producing parahydrogen derived polarization.
16. The method of clause 1, any other suitable clause, or any combination of suitable clauses, wherein the organic solvent further comprises one or more of methanol, ethanol, chloroform, dichloromethane, or any combination thereof.
17. The method of clause 1, any other suitable clause, or any combination of suitable clauses, wherein the protein solution is aqueous.
18. The method of clause 1, any other suitable clause, or any combination of suitable clauses, further comprising diluting the solvent to minimize a concentration of organic solvent therein.
19. The method of clause 1, any other suitable clause, or any combination of suitable clauses, wherein the solvent is diluted at a ratio approximately in a range of about 1:10 to about 1:100.
20. The method of clause 1, any other suitable clause, or any combination of suitable clauses, wherein the ligand comprises 4-amidinopyridine, 2,4-diaminopyrimidine, trimethoprim, or any combination thereof.
21. The method of clause 1, any other suitable clause, or any combination of suitable clauses, wherein transferring the first solution to the detector further comprises injecting the hyperpolarized molecule into an NMR spectrometer.
22. The method of clause 1, any other suitable clause, or any combination of suitable clauses, wherein the injecting is automated.
23. The method of clause 1, any other suitable clause, or any combination of suitable clauses, wherein observing a change in the NMR signal of the hyperpolarized ligand further comprises measuring a change in spin rate of the hydrogens in the ligand.
24. The method of clause 1, any other suitable clause, or any combination of suitable clauses, wherein observing the change in the NMR signal of the hyperpolarized ligand further comprises one or more of observing a spin-spin (R₂) relaxation of one or more hyperpolarized ligand spins or detection of a change in the binding of the hyperpolarized ligand to identify binding of the ligand of interest.
25. The method of clause 1, any other suitable clause, or any combination of suitable clauses, wherein the change in the binding of the hyperpolarized ligand is identified from one or more of spin-lattice (R₁) relaxation rate, cross-relaxation rate, chemical shift, and molecular self-diffusion measured by pulsed field gradient NMR.
26. The method of clause 1, any other suitable clause, or any combination of suitable clauses, further comprising calculating a binding affinity of the ligand of interest.
27. The method of clause 1, any other suitable clause, or any combination of suitable clauses, further comprising optimizing the magnetic field for detection sensitivity based on the hyperpolarized ligand.
28. The method of clause 1, any other suitable clause, or any combination of suitable clauses, wherein the ligand is not modified following hyperpolarization.
29. The method of clause 1, any other suitable clause, or any combination of suitable clauses, further comprising optimizing a mixing ratio to lower a volume of the first solution that is mixed with the protein solution while increasing the ligand concentration during hyperpolarization.
30. The method of clause 1, any other suitable clause, or any combination of suitable clauses, further comprising adjusting a concentration of one or more of a second ligand, a polarization catalyst, an exchange rate in the polarization process, a reaction rate in the polarization process, or any combination thereof.
31. The method of clause 1, any other suitable clause, or any combination of suitable clauses, wherein the hyperpolarization process further comprises bubbling a para-enriched hydrogen gas into the organic or other solvent.
32. The method of clause 1, any other suitable clause, or any combination of suitable clauses, wherein the para-enriched hydrogen gas is delivered at a pressure of about 10 bar.
33. A method for creating a polarizable ligand for use in detecting the interaction of a protein with competitively binding ligands, the method comprising:
introducing a signal amplification by reversible exchange (SABRE) catalyst or a reaction site for a hydrogenative polarization transfer catalyst to a first ligand in a solvent to produce hyperpolarization of the first ligand; and
mixing hyperpolarized first ligand with a protein solution having a second ligand admixed therein to form a solution,
such that a signal of the first ligand in the presence of the second ligand differs from a signal of the first ligand in the absence of the second ligand.
34. The method of clause 33, any other suitable clause, or any combination of suitable clauses, wherein the solvent is an organic solvent.
35. The method of clause 33, any other suitable clause, or any combination of suitable clauses, wherein the solvent is a water-based solvent.
36. The method of clause 33, any other suitable clause, or any combination of suitable clauses, wherein the step of introducing the catalyst to the first ligand in a solvent to produce hyperpolarization of the first ligand forms a hyperpolarized first ligand solution.
37. The method of clause 33, any other suitable clause, or any combination of suitable clauses, wherein further comprising injecting the solution into an NMR spectrometer.
38. The method of clause 33, any other suitable clause, or any combination of suitable clauses, wherein the injection is automated.
39. The method of clause 33, any other suitable clause, or any combination of suitable clauses, wherein the signal amplification by reversible exchange (SABRE) transfer comprises [Ir(IMeMes)(COD)]Cl, [Ir(^{Me}IMes)(COD)]Cl, and [Ir(κC,N—NHC)(COD)]BPh₄ (IMeMes=1-(2,4,6-trimethylphenyl)-3-methylimidazol-2-ylidene, COD=1,5-cyclooctadiene, ^{Me}IMes=1,3-bis(2,4,6-trimethylphenyl)imidazol-2-ylidene, and κ-C,N—NHC=1-(2,4,6-trimethylphenyl)-3-(1-pyrazolylmethyl)imidazol-2-ylidene, 1-(2,4,6-trimethylphenyl)-3-(2-pyridylmethyl)imidazol-2-ylidene, 1-(2,6-diisopropylphenyl)-3-(1-pyrazolylmethyl)imidazol-2-ylidene, diisopropylphenyl)-3-(2-pyridylmethyl)imidazol-2-ylidene, BPh₄=tetraphenylborate), or any combination thereof.
40. The method of clause 33, any other suitable clause, or any combination of suitable clauses, further comprising adjusting a concentration of one or more of the second ligand, the polarization transfer catalyst, or an exchange rate in the catalyst-ligand complex.
41. The method of clause 34, any other suitable clause, or any combination of suitable clauses, wherein introducing the transfer catalyst further comprises bubbling a para-enriched hydrogen gas into the organic solvent.
42. The method of clause 33, any other suitable clause, or any combination of suitable clauses, wherein the para-enriched hydrogen gas is delivered at a pressure of about 10 bar.
43. The method of clause 33, any other suitable clause, or any combination of suitable clauses, wherein a concentration of the second ligand in the protein solution is approximately in a range of about 10 micromolars to about 500 micromolars.
44. The method of clause 33, any other suitable clause, or any combination of suitable clauses, further comprising adjusting a concentration of the second ligand in the protein solution in response to expected binding affinities.
45. A method for creating a polarizable ligand for use in detecting the interaction of a protein with competitively binding ligands, the method comprising:
designing a first ligand to the protein comprising a binding site to a signal amplification by reversible exchange (SABRE) catalyst or a reaction site for a hydrogenative polarization transfer catalyst;
introducing the catalyst to the first ligand in a solvent to produce hyperpolarization of the first ligand; and
mixing hyperpolarized first ligand with a protein solution having a second ligand admixed therein to form a solution,
such that a signal of the first ligand in the presence of the second ligand differs from a signal of the first ligand in the absence of the second ligand.
46. The method of clause 45, any other suitable clause, or any combination of suitable clauses, wherein the solvent is an organic solvent.
47. The method of clause 45, any other suitable clause, or any combination of suitable clauses, wherein the solvent is a water-based solvent.
48. The method of clause 45, any other suitable clause, or any combination of suitable clauses, wherein the step of introducing the catalyst to the first ligand in a solvent to produce hyperpolarization of the first ligand forms a hyperpolarized first ligand solution.
49. The method of clause 45, any other suitable clause, or any combination of suitable clauses, wherein further comprising injecting the solution into an NMR spectrometer.
50. The method of clause 45, any other suitable clause, or any combination of suitable clauses, wherein the injection is automated.
51. The method of clause 45, any other suitable clause, or any combination of suitable clauses, wherein the signal amplification by reversible exchange (SABRE) transfer comprises [Ir(IMeMes)(COD)]Cl, [Ir(^{Me}IMes)(COD)]Cl, and [Ir(κC,N—NHC)(COD)]BPh₄ (IMeMes=1-(2,4,6-trimethylphenyl)-3-methylimidazol-2-ylidene, COD=1,5-cyclooctadiene, ^{Me}IMes=1,3-bis(2,4,6-trimethylphenyl)imidazol-2-ylidene, and κ-C,N—NHC=1-(2,4,6-trimethylphenyl)-3-(1-pyrazolylmethyl)imidazol-2-ylidene, 1-(2,4,6-trimethylphenyl)-3-(2-pyridylmethyl)imidazol-2-ylidene, 1-(2,6-diisopropylphenyl)-3-(1-pyrazolylmethyl)imidazol-2-ylidene, diisopropylphenyl)-3-(2-pyridylmethyl)imidazol-2-ylidene, BPh₄=tetraphenylborate), or any combination thereof.
52. The method of clause 45, any other suitable clause, or any combination of suitable clauses, further comprising adjusting a concentration of one or more of the second ligand, the polarization transfer catalyst, or an exchange rate in the catalyst-ligand complex.
53. The method of clause 46, any other suitable clause, or any combination of suitable clauses, wherein introducing the transfer catalyst further comprises bubbling a para-enriched hydrogen gas into the organic solvent.
54. The method of clause 45, any other suitable clause, or any combination of suitable clauses, wherein the para-enriched hydrogen gas is delivered at a pressure of about 10 bar.
55. The method of clause 45, any other suitable clause, or any combination of suitable clauses, wherein a concentration of the second ligand in the protein solution is approximately in a range of about 10 micromolars to about 500 micromolars.
The method of clause 45, any other suitable clause, or any combination of suitable clauses, further comprising adjusting a concentration of the second ligand in the protein solution in response to expected binding affinities.
56. A method for measuring interactions between a ligand and a protein, the method comprising:
hyperpolarizing a ligand in a solvent using para-hydrogen to form a first solution; transferring the first solution to a detector;
mixing the first solution with a protein solution, the protein solution optionally having one or more ligands of interest therein; and
determining interactions of the hyperpolarized ligand with the protein and optionally with one or more ligands of interest by observing a change in an NMR signal of the hyperpolarized ligand,
wherein the ligand includes one or more binding sites for a polarization transfer catalyst and interaction with the one or more ligands of interest.
57. A method for creating a polarizable ligand, the method comprising introducing a binding site for a non-hydrogenative polarization transfer catalyst or a reaction site for a hydrogenative polarization catalyst, as a modification to a ligand of the protein, wherein the modification provides formation of a catalyst-ligand complex or the causation of a hydrogenation reaction to hyperpolarize the ligand.
58. The method of claim 57, wherein the binding site for a non-hydrogenative polarization transfer catalyst comprises use of a SABRE transfer catalyst.
59. The method of claim 57, wherein the modification of the ligand results in a weak binding affinity, where the ligand is in fast exchange with its protein bound form.
60. The method of claim 57, wherein the hyperpolarizable ligand has a dissociation constant with the protein between 10 micromolar and 500 micromolar.
61. The method of claim 57, wherein the hyperpolarizable ligand binds competitively to the protein with one or more ligands of interest.
62. The method of claim 57, wherein the SABRE transfer catalyst comprises [Ir(IMeMes)(COD)]Cl, [Ir(^{Me}IMes)(COD)]Cl, and [Ir(κC,N—NHC)(COD)]BPh₄ (IMeMes=1-(2,4,6-trimethylphenyl)-3-methylimidazol-2-ylidene, COD=1,5-cyclooctadiene, ^{Me}IMes=1,3-bis(2,4,6-trimethylphenyl)imidazol-2-ylidene, and κ-C,N—NHC=1-(2,4,6-trimethylphenyl)-3-(1-pyrazolylmethyl)imidazol-2-ylidene, 1-(2,4,6-trimethylphenyl)-3-(2-pyridylmethyl)imidazol ylidene, 1-(2,6-diisopropylphenyl)-3-(1-pyrazolylmethyl)imidazol-2-ylidene, 1-(2,6-diisopropylphenyl)-3-(2-pyridylmethyl)imidazol-2-ylidene, BPh₄=tetraphenylborate), or any combination thereof.

The use of the term “or” in the claims is used to mean “and/or” unless explicitly indicated to refer to alternatives only or the alternatives are mutually exclusive, although the disclosure supports a definition that refers to only alternatives and “and/or.”

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

### Example 1

### Exemplary Experimental Procedures

In the instant example, hydrogen gas enriched to a level of ˜50% para-content was prepared by passing room temperature hydrogen gas over iron (III) oxide spin-flip catalyst (Sigma-Aldrich, St. Louis, Mo.) in a heat exchanger, which was immersed in liquid nitrogen The ligand sample for hyperpolarization comprises 20 mM 4-amidinopyridine hydrochloride (Alfa Aesar, Ward Hill, Mass.) in methanol-d₄ (Cambridge Isotope Libraries, Andover, Mass.) The sample contained 3.5 mM of the pre-catalyst [Ir(Me)(IMes)COD]Cl, which was synthesized according to a previously established protocol. For the experiments at low concentration, this stock solution of ligand was diluted to 1.5 mM and 0.3 mM catalyst. For the SABRE experiments, the para-enriched hydrogen was bubbled through the sample solution at a pressure of 8.3·10⁵ Pa and at 294 K. Bubbling was performed for 30 s at a field of 6.5 mT generated by a solenoid coil (diameter 22 cm and length 28 cm). After this polarization transfer step, the sample was pushed to a sample loop using the pressure of the H₂ gas. The hyperpolarized sample was injected into a NMR flow-cell concomitantly with a sample of 50 mM sodium phosphate buffer in D₂O (pH 7.5), or a sample of trypsin (Alfa Aesar) at 1 mM or 18 μM dissolved in the same buffer. Where indicated, 2,2′-bipyridine (Sigma-Aldrich) at 10 mM or 2.5 mM concentration was included with the protein solution. The two solutions mixed in a Y-mixer before entering the magnet. The sample injector that was used for this purpose is described elsewhere. Briefly, both samples were pushed from an injection loop made of poly ether ether ketone (PEEK) tubing of 0.5 mm inner diameter. Two high pressure syringe pumps (Models 500D and 1000D, Teledyne Isco, Lincoln, Nebr.) were filled with water and used to transfer the sample from the injection loop to the Y-mixer and subsequently into the flow-cell. Flow rates were set to 110 ml/minute and 150 ml/minute, respectively. The injection time was 128 ms, during which the pump was active before sample mixing. The time after mixing but before sample reaching flow cell was 1070 ms, and the stabilization time before triggering the NMR experiment was 500 ms. An measurements were performed with a TXI-probe (Bruker Biospin, Billerica, Mass.). A single scan CPMG experiment was performed to find the R₂ relaxation rates of the ¹H spins of the ligand 4-amidinopyridine hydrochloride. A water suppression sequence was used prior to collecting the echoes, where EBURP pulses of 20 ms were applied to selectively excite the solvent signal, followed by dephasing using pulsed field gradients (G_{x,y,z}=70 G/cm; 1 ms). For the CPMG block, a pulsing delay of 1696.2 μs was used, and 64 points were collected per echo. The total experiment time was 10.4 seconds.

### Example 2

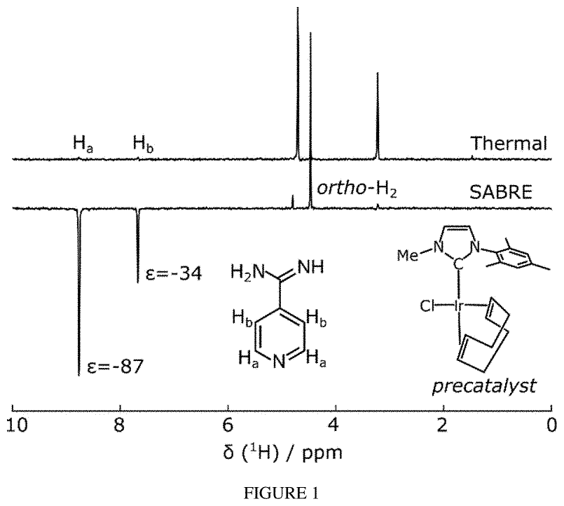

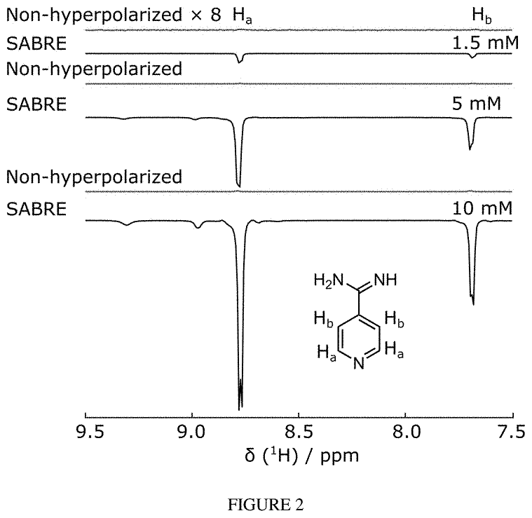

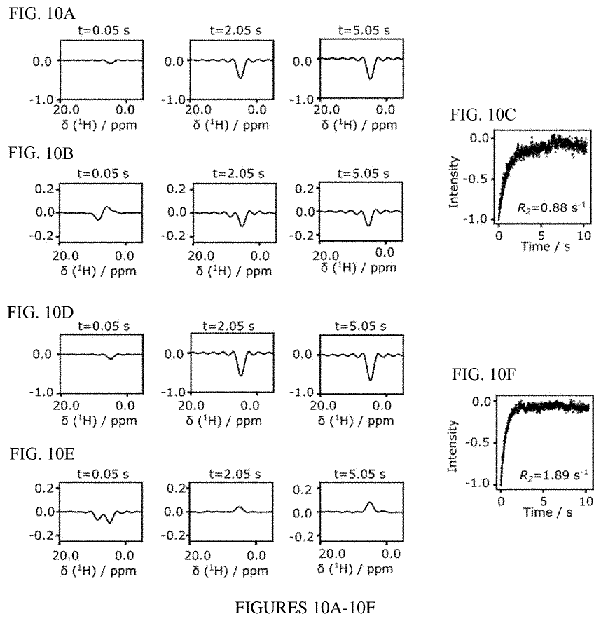

The instant example provides serine proteases including trypsin are inhibited by amidine containing ligands including benzamidine, forming a salt bridge with an aspartate residue in the active site of the protein. Although the amidine group contains nitrogen atoms, its presence in the cationic form would prevent efficient catalyst binding. SABRE hyperpolarization of benzamidine was not observed using a typical catalyst [Ir(^{Me}IMes)(COD)]Cl (COD=cyclooctadiene, ^{Me}IMes=4,5-dimethyl-1,3-bis(2,4,6 trimethylphenyl)imidazol-2-ylidene). The putative ligand chosen for hyperpolarization was 4-amidinopyridine (FIG. 1). This molecule contains an N atom at the site most distant from the expected trypsin binding site. For the resulting molecule 4-amidinopyridine, SABRE hyperpolarization was observable using [Ir(^{Me}IMes)(COD)]Cl, however, higher signal enhancements were obtained with the asymmetric catalyst [Ir(IMeMes)(COD)]Cl (IMeMes=1-(2,4,6-trimethylphenyl)-3-methylimidazol-2-ylidene. The active form of this catalyst is in the following referred to as Ir(IMeMes). Signal enhancements ranging from −87 and −34 for 1.5 mM 4-amidinopyridine to −230 and −110 for 10 mM 4-amidinopyridine, for the H atoms in the ortho and meta positions with respect to the N was obtained. The nuclear spin polarization increases from 0.003% for ¹H at a magnetic field of 9.4 T at 298 K to 0.26% and 0.69% for the Hₐ enhancement values of −87 and −230, respectively. The spectrum for the 1.5 mM condition is shown in FIG. 1. This condition was used for the protein-ligand interaction data at lower concentration (FIG. 10). SABRE NMR spectra for the other ligand concentrations are included in FIG. 2. Without being bound by any theory, this could confirm that the heterocyclic ring promotes binding to the polarization transfer catalyst. The difference in polarization efficiency between the two catalysts could be attributed to the reduced steric hindrance in the asymmetric catalyst, as the para-substituted substrates can also exhibit steric effects.

### Example 3

Despite the ability to hyperpolarize 4-amidinopyridine, the methanol solvent used in FIG. 1 would not be conducive to biological applications such as the characterization of ligand binding. For this reason, SABRE polarization was attempted in a mixture of 50% v/v of methanol-d₄ and D₂O buffer. Under these conditions, the enhancement decreased from −93 to −3 for Hₐ and −46 to −1 for H_{b}, which would be insufficient for the experiment. The signals were further reduced if the protein was included in the mixture.

Given that the Ir(IMeMes) polarization transfer catalyst is incompatible with a one-pot reaction mixture that includes the protein, a two-step process was designed for characterizing the protein-ligand interactions using SABRE hyperpolarization. The molecule to be hyperpolarized separately underwent polarization transfer from para-hydrogen in methanol-d₄, and was subsequently mixed with a protein solution. This two-step procedure is congruous with previous experiments employing D-DNP for the determination of ligand binding.

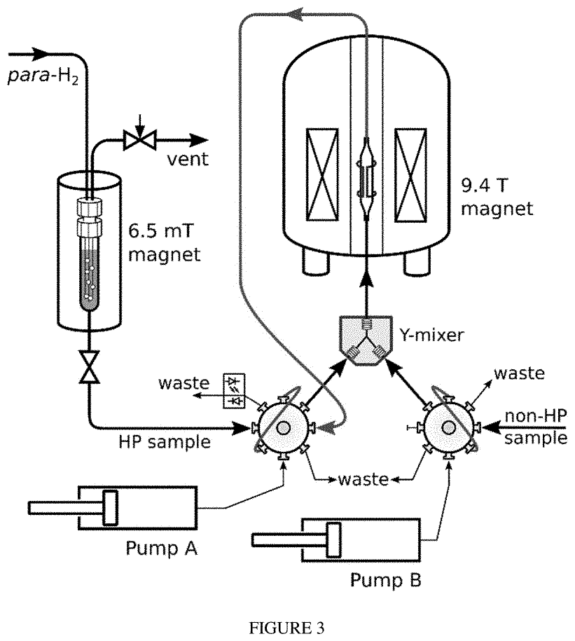

For SABRE polarization, the solution of the putative ligand with polarization transfer catalyst in methanol-d₄ underwent bubbling with para-hydrogen gas (FIG. 3). These conditions are optimal for polarization transfer. The sample was located in an electromagnet producing the required field of 6.5 mT. Following this polarization step, a discharge valve was opened. Under the pressure of the hydrogen gas, the solution was delivered to an injection valve with sample loop. Injection into a flow-cell installed in the 9.4 T NMR magnet was driven by water from high-pressure syringe pumps, simultaneously for the putative ligand and the protein sample. The two samples mixed in a Y-mixer prior to entering the NMR magnet. A stationary mixture in the flow-cell was obtained by switching the injection valve prior to NMR data acquisition.

### Example 4

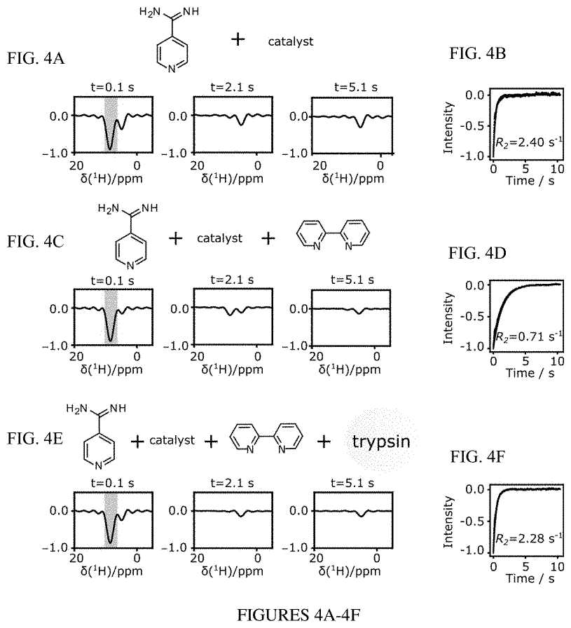

The instant example provides Single-scan Carr-Purcell-Meiboom-Gill (CPMG) NMR experiments were acquired to measure the transverse relaxation rate (R₂) of the ¹H spins of the putative ligand molecule. Spectra obtained from Fourier transforms of selected individual spin echoes are shown in FIGS. 4A-4F. FIG. 4A contains signals from the ligand alone, where hyperpolarized ligand solution in methanol-d₄ was mixed at a ratio of 3:7 (v/v) with a D₂O buffer that did not contain any protein. The hyperpolarized signal from the putative ligand near 8 ppm is strong in the first echo, and decays during the experimental time. The water signal near 4.7 ppm was suppressed using selective pulses and pulsed field gradients. A residual water signal is visible in the spectra, as the syringe pumps used to drive the samples were filled with H₂O. The spectral resolution is limited by the echo time in the CPMG experiment, which is 1.7 ms. The two peaks from the hyperpolarized 4-amidinopyridine molecule seen in FIG. 1 merge into one observed signal. Still, this signal of interest is well separated from the residual water signal, and can be analyzed to result in an averaged relaxation rate for the putative ligand.

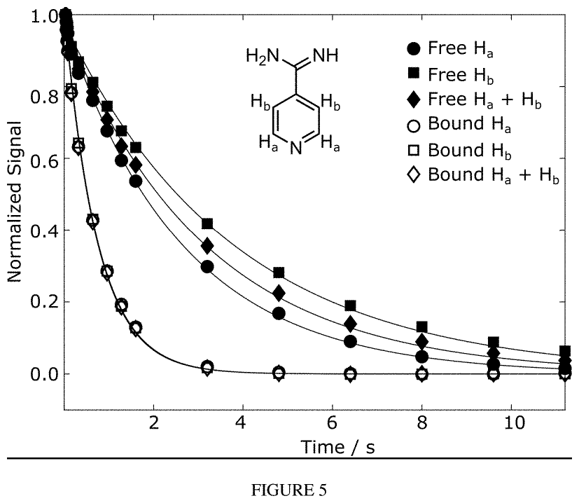

After integration of the signals from each echo, an exponential decay is observed (FIG. 4B). The R₂ relaxation is obtained by fitting a single exponential curve, here resulting in a value of 2.40 s⁻¹ for the 4-amidinopyridine without the presence of protein. This relaxation rate is much larger than R₂=0.32 s⁻¹ that was determined from a non-hyperpolarized NMR experiment for the same molecule (FIG. 5). Without being bound by any theory, the difference in these relaxation rates could attributed to the presence of the polarization transfer catalyst, as a direct consequence of binding of the molecule to the Ir center of the catalyst. Similar relaxation changes due to catalyst binding have previously been observed. After including a chelating ligand, 2,2′-bipyridine, with the buffer solution to trap the catalyst, the relaxation rate of the hyperpolarized signal was found to be slower, with R₂=0.71 s⁻¹ (FIGS. 4C and 4D). Finally, upon the addition of the trypsin protein, the relaxation rate increased to R₂=2.28 s⁻¹ (FIGS. 4E and 4F).

### Example 5

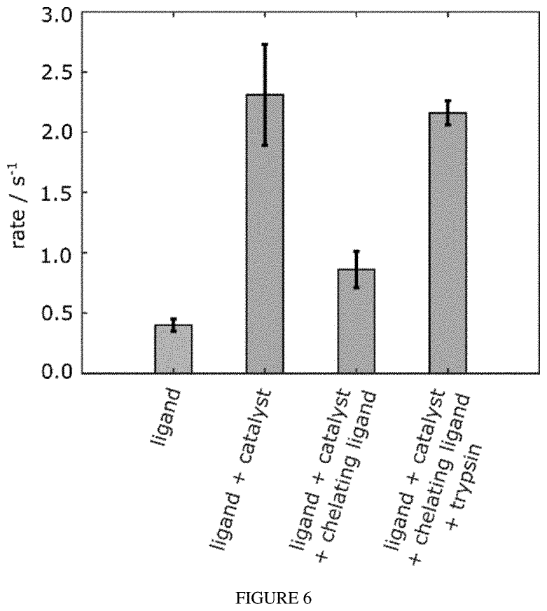

The instant example provides a summary of the measurements under the different experimental conditions, including several repetitions, is included in Table 1. The changes in the observed relaxation rates are represented in FIG. 6. The comparison of the non-hyperpolarized experiment with R₂-relaxation rate 0.39±0.06 s⁻¹ (green bar) with the “ligand+catalyst” (first gray bar) indicates a significant relaxation effect due to the interaction of the hyperpolarized molecule with the polarization transfer catalyst with the R₂ rate 2.30±0.44 s⁻¹. This effect is largely reversed by the addition of the 2,2′-bipyridine (second gray bar). Without being bound by any theory, the chelating agent therefore could significantly improve the ability to measure the relaxation properties of the free ligand with values 0.86±0.15 s⁻¹. A smaller difference in the rates between the “ligand” (green bar) and the “ligand+catalyst+chelating ligand” (second gray bar), which narrowly exceeds the error limit, could be attributed to a residual fraction of catalyst not trapped by the 2,2′-bipyridine chelating ligand. Finally, without being bound by any theory, the inclusion of the protein could lead to a significant increase in the relaxation rate with R₂ values 2.16±0.10 s⁻¹ (third gray bar). This increase is due to the slower tumbling of the protein-ligand complex in solution, hence proving the binding of the ligand to the protein. Importantly, it can be seen that, firstly, the change in the relaxation rate that could demonstrate the binding and therefore represents the result of the experiment is highly significant. Secondly, the change is observable after removing the relaxation contribution that is introduced by the polarization transfer catalyst.

TABLE 1
The experimental parameters and the fitted
R₂ relaxation rate for each experiment.

| [ligand]/ | [catalyst]/ | [bipyridine]/ | [protein]/ | [ligand]/ | |
|---|---|---|---|---|---|
| mM | mM | mM | mM | [protein] | R₂/s⁻¹ |
| 7.30 | 1.27 | — | — | — | 2.40 |
| 7.22 | 1.26 | — | — | — | 1.86 |
| 7.62 | 1.33 | — | — | — | 2.68 |
| 7.90 | 1.38 | 2.81 | — | — | 1.01 |
| 6.80 | 1.12 | 3.95 | — | — | 0.71 |
| 7.32 | 1.28 | 2.87 | — | — | 0.86 |
| 5.87 | 0.93 | 3.02 | 0.33 | 17.8 | 2.28 |
| 6.90 | 1.21 | 2.53 | 0.28 | 24.4 | 2.10 |
| 6.43 | 1.12 | 2.73 | 0.27 | 23.5 | 2.11 |
| 0.134 | 0.03 | 1.14 | — | — | 0.88 |
| 0.125 | 0.03 | 1.12 | 0.0072 | 17.4 | 1.89 |

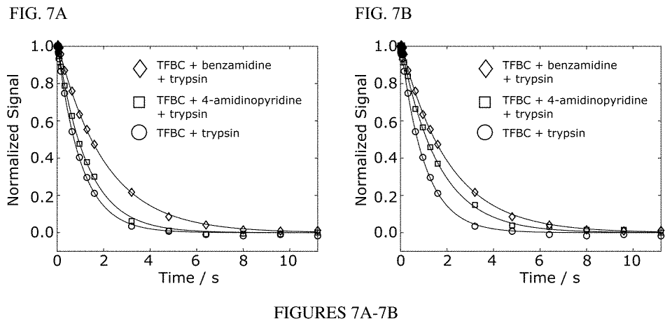

The result of this experiment is in agreement with competitive binding measurements of 4-amidinopyridine to trypsin measured by NMR (FIG. 7). These measurements could indicate a dissociation constant for 4-amidinopyridine that lies in-between the those of the related known ligands for trypsin, benzamidine and 4-(trifluoromethyl)benzene-1-carboximidamide.

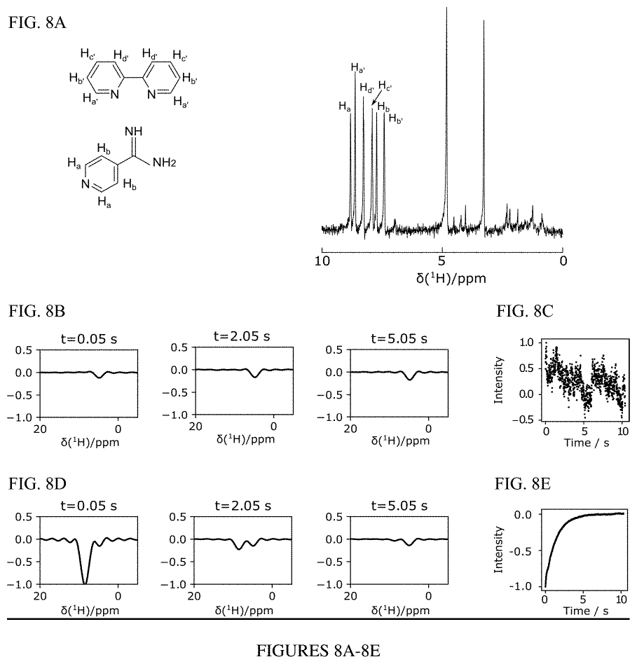

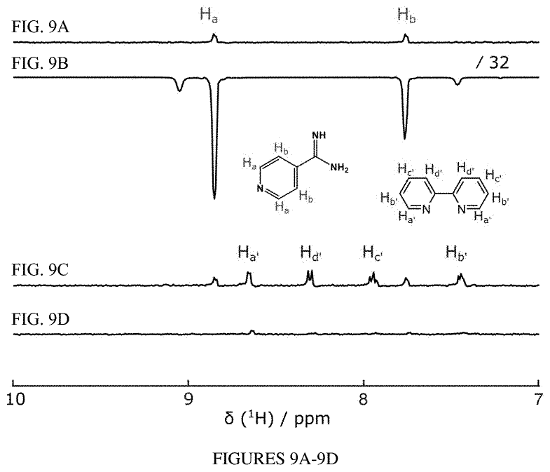

The signals of the 2,2′-bipyridine chelating agent would appear in the same spectral region as the signals of interest from the ligand. An efficient transfer of hyperpolarization to 2,2′-bipyridine would not be expected because firstly, this compound is not present in the sample during the SABRE hyperpolarization step in the experiment, and secondly its off-rate is slowed due to its ability to form a bidentate complex with Ir. Nevertheless, to ensure that the rates are determined from the ligand peaks of interest, a control experiment was performed, where the ligand was not included in the reaction mixture. The resulting spectra are shown in FIG. 8. In this control experiment, no exponential decay is observed for the integrated spectral region, indicating an absence of signal contributions from the chelating ligand, without being bound by any theory. Moreover, when the 2,2′-bipyridine is added to a sample of the activated catalyst and ligand 4-amidinopyridine for a one-pot experiment performed in the NMR tube, no SABRE hyperpolarized signals were observed (FIG. 9).

### Example 6

The instant example provides an exploration of concentration limits under current experimental conditions where both the protein and the ligand concentration are lowered for the data of FIGS. 10A-10F. A smaller volume of ligand solution, 500 μl, with a stock concentration of 1.5 mM, was hyperpolarized. After mixing, the protein concentration reached to the single digit micromolar level, and the ligand was in the range of 100-150 μM. Under these conditions, the signal of the hyperpolarized ligand can be obscured by parts of the solvent line (FIGS. 10A and 10D, top panels). In the bottom panels of these figures, the solvent signal was reduced by subtracting a reference spectrum that was scaled to the maximum solvent signal intensity. The binding of the ligand is identified by comparing the relaxation rates obtained from the fit in FIGS. 10C and 10F.

Nuclear spin hyperpolarization offers significant advantages in the detection of protein-ligand interactions, by allowing a reduction in the ligand concentration. Under conditions of fast exchange between free and bound forms of the ligand, as is the case for 4-amidinopyridine and trypsin, the protein concentration can be reduced to a level several times below the ligand concentration. The reduction in concentration facilitates working with proteins that are unstable or difficult to purify.

Although the fluctuations in the echo signals seen in FIGS. 10B and 10E are larger than those in FIG. 4, the experiment at these concentrations is not primarily limited by thermal noise in the spectra. The concentration of the hyperpolarized ligand in the final solution may be further reduced. Because SABRE hyperpolarization is typically most effective for a ligand concentration in the millimolar range, the concentration in the stock solution for hyperpolarization should not be arbitrarily reduced. Rather, the amount of stock solution that is used in the experiment could be lowered. This goal may preferably be combined with methods that introduce hyperpolarized gas into a smaller volume of liquid to minimize consumption of the ligand and the polarization transfer catalyst. For example, microfluidic techniques that introduce gases into liquids have previously been described. An experiment reducing the ligand concentration would further benefit from the addition of a technique that facilitates the rapid admixing of a small, microliter-range volume of ligand solution to the protein solution.

Several improvements could further increase achievable signals and lower the minimum ligand concentration. Additional water suppression or use of solvents with higher deuteration level would reduce fluctuations due to solvent signal overlap. The experiments could be performed using hydrogen gas with a higher para content. Here, 50% para-hydrogen was produced by cooling hydrogen gas to the temperature of 77 K using liquid nitrogen. Increasing the percentage by producing para-hydrogen at lower temperature could increase the signal enhancement by another factor of three. An additional improvement of at least a factor of two would be realized by changing the ligand concentration during the polarization step. As is known from the literature, optimal polarization efficiency could be achieved in a range of catalyst and ligand concentration, where a sufficient fraction of the ligand is bound to the catalyst. Based on the data in FIG. 2, a ligand concentration of 10 mM during the polarization step could result in a higher signal enhancement. A lower concentration was used in this work in order to achieve a low ligand concentration after mixing with the protein at a moderate volume-to-volume ratio in the experimental setup as implemented. The mixing ratio could be further optimized to lower the volume of hyperpolarized ligand solution that is introduced, while increasing the ligand concentration in the hyperpolarization step.

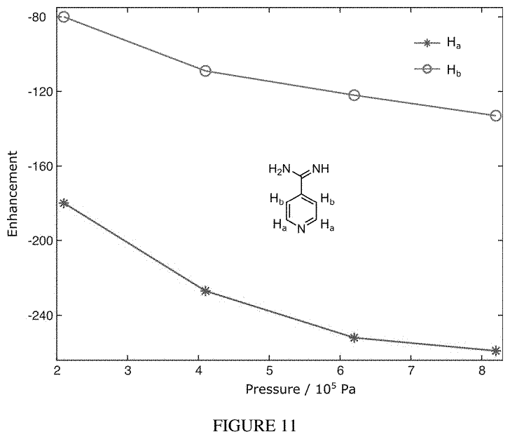

In addition to the other reagents, the achievable signal enhancement can depend on the hydrogen gas pressure. The pressure dependence of signal enhancement for this ligand and catalyst is shown in FIG. 11 over the range of 0.21 to 0.83 MPa. It is evident that the signal enhancement is close to reaching a plateau, indicating that the pressure used in the experiment may be sufficient to achieve near saturation in the metal hydride formation and highest enhancements. The same pressure was also used to effectively drive the sample from the polarization vessel to the sample loop.

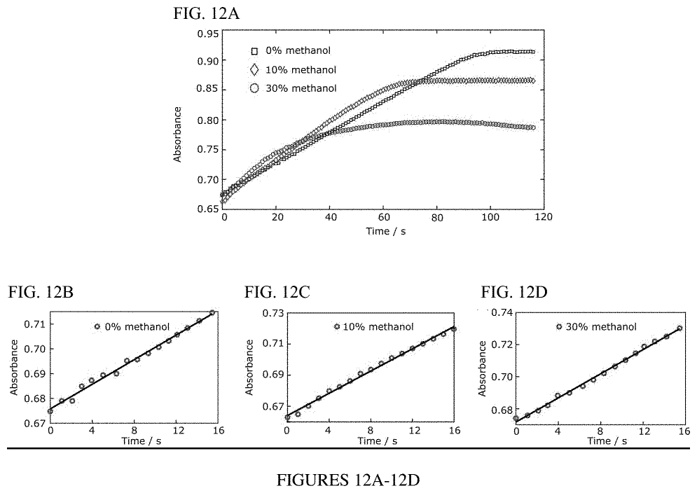

Without being bound by any theory, SABRE hyperpolarization using common polarization transfer catalysts could be readily achieved in polar organic solvents, here methanol. Apart from decreasing the protein concentration, a benefit of a large dilution factor upon mixing of the two solutions in this experiment is that the final concentration of the organic solvent component is reduced. The volume ratio of the experiments in FIGS. 10A-10F resulted in a methanol fraction after admixing the protein of <10%. Without being bound by any theory, proteins are likely to retain their native structure in solutions with a low content of alcohol. Trypsin was previously found to retain the ability to bind a ligand in the presence 30% methanol. Measurements of trypsin catalytic activity confirmed similar initial reaction rate constants in 30% and 10% methanol compared to water, for the first 15 s or reaction time (FIG. 12). Deactivation of the enzyme occurred after approximately 30 or 60 seconds, respectively, i.e. at a much longer time than the duration of the hyperpolarized NMR experiment. A further reduction of ligand solution volume as described above would entail the additional benefit of reducing the methanol concentration in the final sample.

The use of SABRE for the characterization of protein-ligand interactions can be expanded to other ligands containing appropriate functional groups. These may include the —NH₂, —CN groups or the heterocyclic N as demonstrated here. In addition to protons, SABRE hyperpolarization can be achieved for other nuclei, including fluorine. ¹⁹F has been hyperpolarized by SABRE both directly and indirectly through the intermediary of a nearby proton. The method described here can be adapted for ligands containing this nucleus. Similar to previous D-DNP experiments, the observation of fluorine would avoid any interference from the solvent signal. Ligand derived SABRE hyperpolarization may in the future be used for studies of macromolecular structure at the binding site, by employing polarization transfer and using calculations similar to those demonstrated by other hyperpolarization methods. An additional generalization of the experiment includes the use of one molecule with weak affinity and fast exchange rate as a reporter ligand, which becomes displaced upon binding of another ligand. This approach would require the identification of only one SABRE hyperpolarizable ligand for screening of a library of other ligands.

### Example 7

Characterization of Protein-Ligand Interactions by Competitive Binding with a SABRE Hyperpolarized Reporter

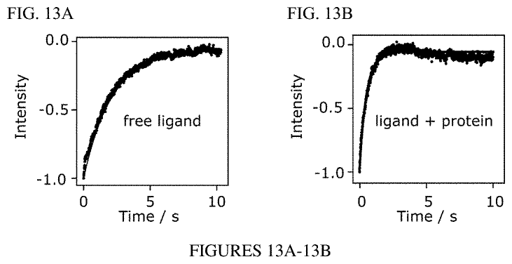

The instant example provides the hyperpolarization of ligand 4-amidinopyridine with an asymmetric SABRE catalyst, as previously described. The relaxation rates of this ligand in the presence and absence of protein were determined from single-scan Carr-Purcell-Meiboom-Gill (CPMG) experiments (FIG. 13). The hyperpolarized ligand was injected into a NMR flow cell. The chelating ligand 2,2′-bipyridine was included to trap the polarization transfer catalyst. NMR measurement was performed with or without admixing of protein. Initially negative, and subsequently decay towards the much smaller positive thermal equilibrium spin polarization. A faster relaxation is observed in the presence of protein, due to averaging of the relaxation rate of the free ligand fraction with the faster rate of the bound fraction.

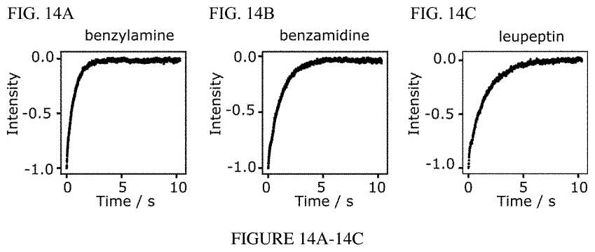

Subsequently, relaxation rates of the same compound, 4-aminidinopyridine, were measured when a ligand of interest was included in the protein solution. In this case, the 4-amidinopyridine acts as a reporter ligand. FIG. 14 shows the result of screening the ligands benzylamine, benzamidine and leupeptin. As the ligand of interest partially displaces the reporter ligand, its observed relaxation rate of changes to fall in-between the rates for free reporter and reporter with protein alone. The weakest ligand of interest, benzylamine, was present at the highest concentration of 150 μM to achieve partial displacement manifested as an observable change in the relaxation rate. In contrast, the strongly binding leupeptin caused a strong change at the much lower concentration of 7 μM. Under the solution conditions of the three experiments, the R₂ relaxation rate was fastest with benzylamine at 1.54 s⁻¹, followed by benzamidine at 0.85 s⁻¹, and leupeptin at 0.59 s⁻¹. Without being bound by any theory, this could indicate that in the first experiment, the smallest fraction of reporter ligand was displaced, with increasing fractions in the second and third experiment.

The partial displacement of the reporter ligand, barring allosteric effects, indicates that the ligand of interest binds to the same binding site of the protein as the reporter ligand. Further, if the dissociation constant (K_{D}) of the reporter ligand is known, it can be used to determine the K_{D} of the other unknown ligands.

### Example 8

The instant example provides exemplary materials and methods utilized in Examples 9-12 as described herein.

Para-hydrogen was produced by passing room temperature hydrogen over iron (III) oxide spin-flip catalyst (Sigma-Aldrich, St. Louis, Mo.) in a heat exchanger immersed in liquid nitrogen at the temperature of 77 K. The para content was 50% as determined from the ratios of the signal intensities of ortho-hydrogen in the para-hydrogen enriched and from room-temperature equilibrated hydrogen.

The sample for hyperpolarization includes 0.3 mM of the asymmetric precatalyst [Ir(IMeMes)(COD)]Cl and 1.5 mM ligand 4-amidinopyridine hydrochloride (Alfa Aesar, Ward Hill, Mass.) in methanol-d₄ (Cambridge Isotope Libraries, Andover, Mass.). The precatalyst was synthesized according to a previously established protocol. For the activation of the precatalyst, para-hydrogen (˜50% para-content) was bubbled through the sample at a pressure of 8.3·10⁵ Pa and at 294 K. The SABRE hyperpolarization was conducted in a 6.5 mT magnetic field that was generated by a solenoid coil (diameter 22 cm and length 28 cm). The non-hyperpolarized sample includes 50 mM sodium phosphate buffer in D₂O (pH=7.6) and 1 mM 2,2′-bipyridine, or of buffer, 2,2′-bipyridine and 40 μM trypsin. For the competition experiments, the competing ligands of interest (500 μM benzylamine, 500 μM benzamidine or 30 μM leupeptin) were included. 5 mM sodium trimethylsilylpropanesulfonate (DSS) was included as a reference compound in the non-hyperpolarized sample.

After the hyperpolarization was established, the sample was delivered to a sample loop using the pressure of the hydrogen gas. Subsequently, the sample was taken to a flow-cell that was pre-installed in the 9.4 T magnet using a high-pressure syringe pump (Model 500D Teledyne Isco, Lincoln, Nebr.). The injector device used for this purpose is described elsewhere. At the same time, the non-hyperpolarized sample was injected using another high pressure syringe pump (Model 1000D, Teledyne Isco). The two samples mixed in a Y-mixer before entering the magnet with a mixing time tₘᵢₓ of 1.05 seconds. For the NMR experiments, a single scan Carr-Purcell-Meiboom-Gill (CPMG) experiment was performed to determine the R₂ relaxation rates of the ¹H spins of the 4-amidinopyridine ligand. Before acquiring the echoes, water suppression was achieved by applying EBURP pulses of 20 ms duration to excite the water signals, and dephasing them by pulsed field gradients. A pulsing delay of 1696.2 μs was used in the CPMG block, and 64 points were collected per echo. The total experiment time was 10.4 seconds.

The echoes measured from the CPMG experiments were multiplied with time symmetric dual exponential window functions and Fourier transformed. The spectra were phased with a constant phase correction value maximizing the real part of the spectrum. A reference water signal (sample without ligand) was subtracted from each echo by scaling to the maximum solvent signal intensity. The ligand signal was then integrated (peak ˜8.1 ppm) and fitted to a single exponential curve to obtain the R₂ rates from each experiment.

The concentrations in the competitive binding experiment were determined after the CPMG experiment from the same samples in the flow cell. The concentration of the reporter ligand [R]₀ was determined by referencing the ¹H NMR signal intensities to a sample of 20 mM of the ligand 4-amidinopyridine in the same flow cell. For the determination of the concentration of the competing ligand [C]₀ and protein [P]₀, the reference DSS signal was used. The dilution factor was determined based on the ¹H NMR signal intensity of DSS and was used to determine the final concentrations, [C]₀ and [P]₀.

The dissociation constant of the reporter ligand K_{D,r} and the total concentrations of reporting ligand [R]₀ and protein [P]₀ were used to determine bound fraction of reporter ligand in non-competition experiment p_{b,r}^{(nc)} (equations 1.5 and 1.6b). The bound fraction of reporting ligand in competition experiment p_{b,r}^{(c)} was calculated from the relative fraction of the bound reporter ligand f and the p_{b,r}^{(nc)} value (equation 1.7).

$$\begin{matrix}Equations & \\ F = 1 - \frac{3 {S}_{enriched}}{4 {S}_{rt}} & ( 1.1 )\end{matrix}$$

$$P + R ⟺ PR \qquad ( 1.2 a )$$

$$P + C ⟺ PC \qquad ( 1.2 b )$$

$${K}_{D , τ} = \frac{[ P ] [ R ]}{[ PR ]} \qquad ( 1.3 a )$$

$${K}_{D , c} = \frac{[ P ] [ C ]}{[ PC ]} \qquad ( 1.3 b )$$

$${[ R ]}_{0} = [ R ] + [ PR ] \qquad ( 1.4 a )$$

$${[ C ]}_{0} = [ C ] + [ PC ] \qquad ( 1.4 b )$$

$${[ P ]}_{0} = [ P ] + [ PR ] + [ PC ] \qquad ( 1.4 c )$$

$${[ PR ]}^{( nc )} = \frac{{⌊ R ⌋}_{0} + {⌊ P ⌋}_{0} + {K}_{D , r} - \sqrt{{( {[ R ]}_{0} + {[ P ]}_{0} + {K}_{D , r} )}^{2} - {{4 [ R ]}_{0} [ P ]}_{0}}}{2} \qquad ( 1.5 )$$

$${p}_{b , r}^{( c )} = \frac{{[ PR ]}^{( c )}}{{[ R ]}_{0}^{( c )}} \qquad ( 1.6 a )$$

$${p}_{b , r}^{( nc )} = \frac{{[ PR ]}^{( nc )}}{{[ R ]}_{0}^{( nc )}} \qquad ( 1.6 b )$$

$$f = \frac{{p}_{b , r}^{( c )}}{{p}_{b , r}^{( nc )}} \qquad ( 1.7 )$$

$${p}_{b , r}^{( c )} = {p}_{b , r}^{( nc )} \cdot \frac{{R}_{2 , r}^{( c )} - {R}_{2 , r}^{( f )}}{{R}_{2 , r}^{( nc )} - {R}_{2 , r}^{( f )}} \qquad ( 1.8 )$$

$${K}_{D , app} = {[ P ]}_{0} ( \frac{1}{{p}_{b , r}^{( c )}} - 1 ) - {[ R ]}_{0} ( 1 - {p}_{b , r}^{( c )} ) \qquad ( 1.9 )$$

$${K}_{D , c} = \frac{{K}_{D . r}}{{K}_{D , app} - {K}_{D , r}} ( {[ C ]}_{0} - {[ P ]}_{0} + {p}_{b , r}^{( c )} \cdot ( {[ R ]}_{0} + \frac{{K}_{D , app}}{1 - {p}_{b , r}^{( c )}} ) ) \qquad ( 1.1 )$$

The p_{b,r}^{(c)}, [R]₀ and [P]₀ values were used to calculate the apparent dissociation constant of the reporter ligand, and using the competing ligand total concentration [C]₀, to calculate the dissociation constant of the competing ligand K_{D,c} (equations 1.9 and 1.10).

### Example 9

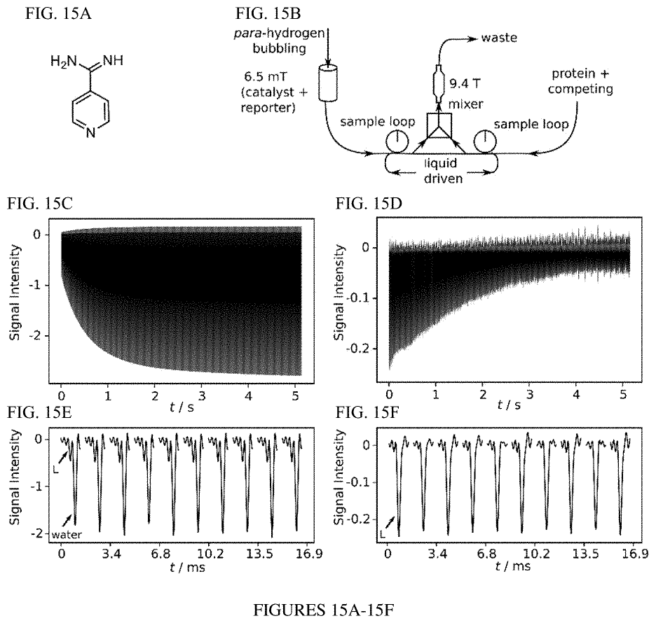

The instant example provides the molecule 4-amidinopyridine (FIG. 15A) to serve as the reporter ligand for the protein trypsin in the later competing experiments. This molecule was injected into an NMR flow cell (FIG. 15B) after hyperpolarization with the asymmetric SABRE catalyst [Ir(IMeMes)(COD)]Cl, as previously described. The proton spin relaxation rates of 4-amidinopyridine in the presence and absence of protein were determined from single-scan Carr-Purcell-Meiboom-Gill (CPMG) experiments. The chelating ligand 2,2′-bipyridine was mixed with the hyperpolarized sample during injection, before the data acquisition. Trapping the catalyst with the chelating ligand alleviates relaxation contributions due to interactions with the reporter ligand, which would be detrimental to the identification of protein binding.

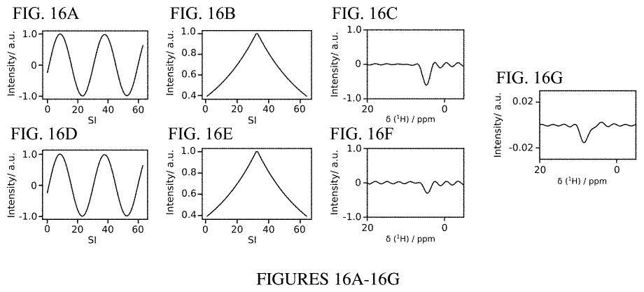

FIG. 16A shows the real part of a CPMG echo that is multiplied with an exponential window function (FIG. 16B) before being Fourier transformed into an NMR spectrum. The water peak at ˜4.7 ppm is the largest in this spectrum; therefore, a separately measured reference water signal (FIG. 16F) is subtracted from the hyperpolarized ligand signal. The largest peak in the spectrum after water subtraction (FIG. 16G), at a chemical shift of 8.1 ppm, contains the signals from both aromatic protons of the 4-amidinopyridine. These signals are not individually resolved due to the short echo time of 1.7 ms, which results in a spectral resolution of 590 Hz. A signal enhancement of ˜100-fold for the reporter ligand facilitates its observation in the presence of the non-hyperpolarized water. A series of spectra corresponding to 3000 CPMG echoes (0-5.1 s) is plotted in FIG. 15C, and the first 10 spectra are shown in FIG. 15E. Because the water chemical shift is off resonance during implementing CPMG pulse train, the imperfect π pulses on the water signal cause the partially excitation of its I_{z} component. Without being bound by any theory, this effect could lead to the growth of water signal with respect to time in FIG. 15C, rather than the decay due to R₂ relaxation. This artifact is removed by applying water subtraction from these spectra, and the results are shown in FIGS. 15D and 15F. As expected for a SABRE experiment, the signal of the reporter ligand has an initially negative intensity and subsequently relaxes towards the negligibly small positive intensity at thermal equilibrium.

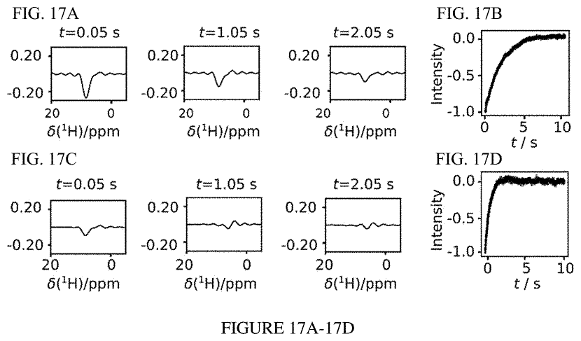

The relaxation process is visible in the signal intensities shown in FIG. 17A, which are integrated from a single CPMG echo train. In some of the spectra, a second peak from the suppressed water signal is visible near 4.7 ppm. A faster relaxation is observed in the presence of protein, that could be due to averaging of the relaxation rate of the free ligand fraction with the faster rate of the bound fraction (FIGS. 17B and 17D). Fitting of a single exponential to the relaxation data resulted in a transverse relaxation rate of 144 μM free reporter ligand, R_{2,s}^{(f)}=0.47±0.01 s⁻¹. In the presence of 11.7 μM trypsin, the relaxation rate for the non-competing reporter ligand increased to R_{2,r}^{(nc)}=1.86±0.13 s⁻¹.

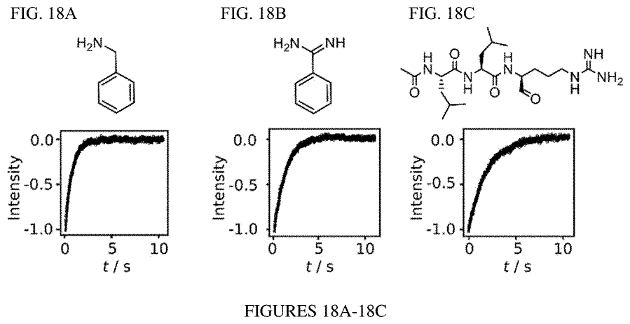

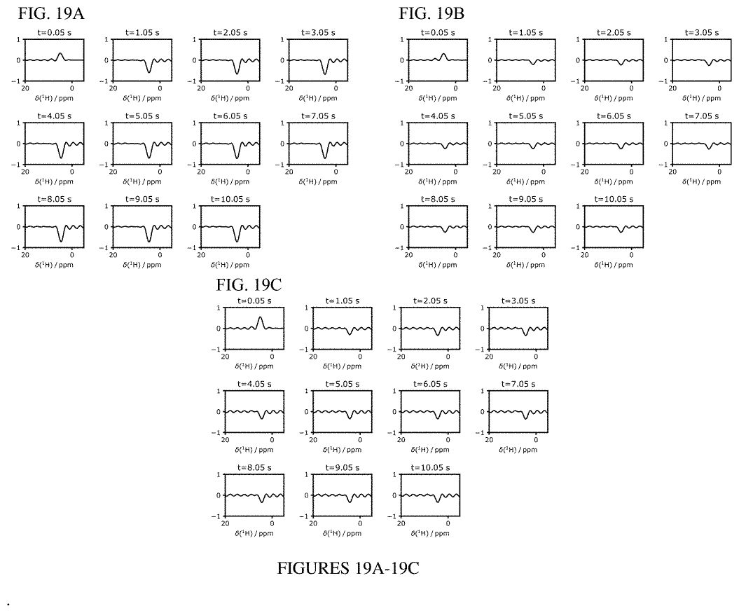

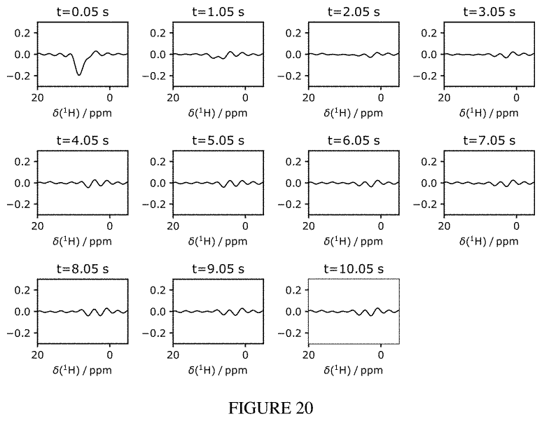

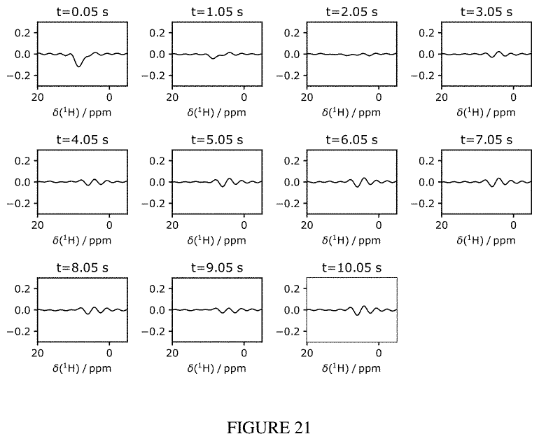

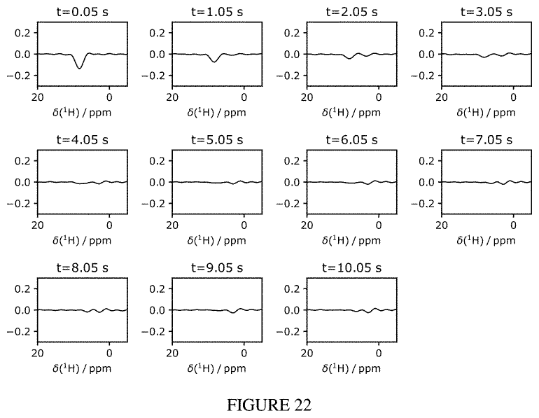

Relaxation rates of the same molecule 4-amidinopyridine were measured when a second ligand for the protein, the competing ligand of interest, was included with the protein solution. FIG. 18 shows the signal integrals resulting from screening the ligands of interest benzylamine, benzamidine and leupeptin. The corresponding spectra from CPMG echo trains, when 4-aminidopyridine is in competition, are shown in FIGS. 19-22. As these ligands partially displace the reporter ligand, its observed relaxation rate changes. The relaxation rate of the reporter ligand after displacement falls in-between the rates for free reporter and reporter with protein alone. The weakest ligand of interest, benzylamine, was present at a concentration of 166 μM to achieve partial displacement manifested as an observable change in the relaxation rate (FIG. 18A). In contrast, the strongly binding leupeptin caused a large change in R₂ relaxation at the much lower concentration of 7 μM (FIG. 18C). Without being bound by any theory, the partial displacement of the reporter ligand, barring allosteric effects, could indicate that the ligand of interest binds to the same binding site of the protein as the reporter ligand.

Under the solution conditions of the experiments, the relaxation rate in competition, R_{2,r}^{(c)}, determined from three separate measurements was fastest with benzylamine at 1.47±0.04 s⁻¹, followed by benzamidine at 0.88±0.06 s⁻¹, and leupeptin at 0.58±0.05 s⁻¹ (Table 2). Without being bound by any theory, these rates could indicate that in the first experiment, the smallest fraction of reporter ligand was displaced, with increasing fractions in the second and third experiment.

TABLE 2
The experimental parameters for the reporter ligand ([R]₀),
protein ([P]₀) and competing ligand ([C]₀) are summarized.
R₂ is the fitted relaxation rate from each experiment.

| | | | | |
|---|---|---|---|---|
| | [catalyst]/ | | | |
| [R]₀/mM | mM | [P]₀/mM | [C]₀/mM | R₂/s⁻¹ |

benzamidine

| | | | | |
|---|---|---|---|---|
| 0.146 | 0.028 | 0.012 | 0.136 | 0.85 |
| 0.159 | 0.032 | 0.02 | 0.149 | 0.88 |
| 0.169 | 0.025 | 0.011 | 0.140 | 0.94 |

benzylamine

| | | | | |
|---|---|---|---|---|
| 0.161 | 0.024 | 0.015 | 0.166 | 1.52 |
| 0.190 | 0.028 | 0.014 | 0.146 | 1.43 |
| 0.160 | 0.032 | 0.015 | 0.185 | 1.47 |

leupeptin

| | | | | |
|---|---|---|---|---|
| 0.180 | 0.027 | 0.0107 | 0.0107 | 0.63 |
| 0.144 | 0.022 | 0.008 | 0.0077 | 0.55 |
| 0.160 | 0.024 | 0.011 | 0.0092 | 0.54 |

### Example 10

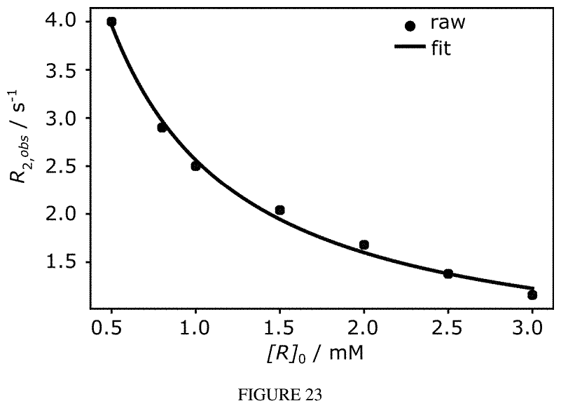

The instant example provides the level of displacement depending on the concentrations and on the dissociation constants of both the reporter and competing ligands. If the dissociation constant of the reporter ligand, K_{D,r}, is known, it can be used to determine the dissociation constant of the competing ligand of interest, K_{D,c}. The K_{D,r} was independently determined to be 152±51 μM from NMR titrations (FIG. 23). The K_{D,c} values of the competing ligands were then determined following ref. [8], resulting in 200±80 μM for benzylamine, 28±8 μM for benzamidine and 0.27±0.14 μM for leupeptin. These K_{D,c} values and associated error ranges were estimated based on the averages and standard deviations of the R₂ values from the three separate measurements, as well as the separately measured K_{D,r} value. The determined values for K_{D,c} correspond to previously reported values of 258.1±56.6 μM, 16.3±1.6 μM and 0.09±0.03 μM for the three ligands, respectively. The slightly weaker affinity measured here for the latter two ligands may be due to the presence of the <10% methanol in the final solution.

An additional error in the measured K_{D,c} can be introduced by binding of the reporter ligand to the polarization transfer catalyst. Although the catalyst is trapped by 2,2′-bipyridine during the NMR measurement, a remaining open coordination site may bind a ligand molecule, potentially causing changes in concentration or relaxation. There was no significant difference in R₂ values between non-hyperpolarized experiments without catalyst, and SABRE experiments with inactivated catalyst. Without being bound by any theory, it could be inferred that the exchange rates of the free and catalyst-bound reporter ligands were too slow to contribute to the observed relaxation. However, the catalyst may sequester ligand at a 1:1 ratio. Accounting for the resulting reduction in free ligand concentration would cause the K_{D,c} values to increase by at most 10%. This contribution to the measured values is neglected in the above discussion.

### Example 11

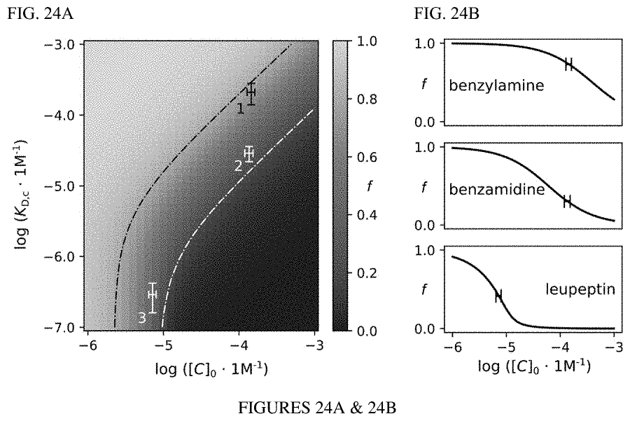

For a successful determination of K_{D,c} from the experiment, the ligand and protein concentrations should be chosen to cause a partial displacement of the reporter ligand and, consequently, a relaxation rate that is different from the rates of free reporter and reporter in presence of the protein alone. The optimal concentration ranges can be predicted from calculating the relative fraction of bound reporter ligand in the competing and non-competing experiments, f=p_{b,r}^{(c)}/p_{b,r}^{(nc)} (equations 1.2-1.7). In FIG. 24A, the fraction f is shown for given concentrations of the protein and reporter ligand similar to the experimental conditions. The concentration of the competing ligand is varied along the vertical, and the dissociation constant of the competing ligand, K_{D,c}, along the horizontal axis. Conditions with f values in the range of 0.2-0.8, reflective of the desired partial displacement, are enclosed by the dash-dotted curves. The concentrations of the three competing ligands used in the experiments are indicated in the figure according to their determined K_{D,c} values, falling within this range.

Under conditions where the fraction of bound reporter ligand is small and the reporter ligand is in fast exchange, f equals the value α=(R_{2,s}^{(c)}−R_{2,r}^{(f)})/(R_{2,r}^{(nc)}−R_{2,r}^{(f)}). The parameter α is calculated solely from the experimentally determined transverse relaxation rates. Based on Monte Carlo simulations and error analysis, it was previously concluded that the most reliable value of K_{D,c} can be obtained when the a value is near 0.5.

The concentration limits for optimal determination of K_{D,c} in general depend on the relative values of the dissociation constants of the reporter and competing ligands. This dependence is illustrated in FIG. 24B, which shows the f values in cross-sections along the horizontal axis of FIG. 24A. For strongly binding ligands such as leupeptin, the optimal f values are achieved at a lower concentration and in a narrower concentration range compared to the weaker ligands.

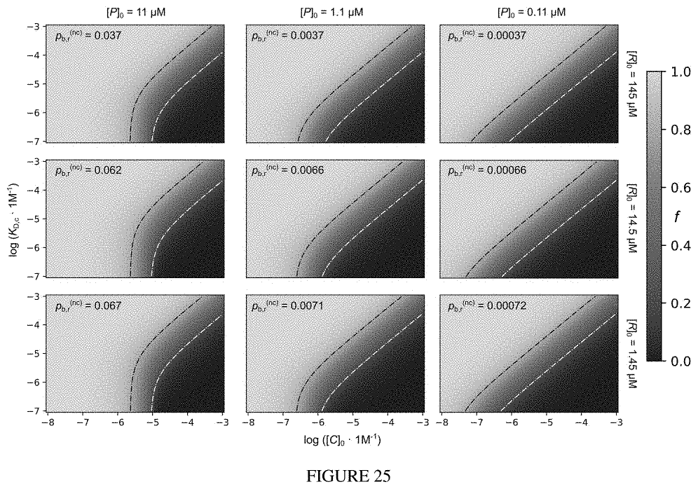

Under the present experimental conditions, irrespective of K_{D,c} values, a competing ligand concentration of ˜1 μM or lower does not cause a significant displacement of the bound reporter ligand and should not be used for K_{D,c} determination. FIG. 25 explores, for this protein and ligand system, how lowering the concentrations of protein or reporter ligand may allow a concomitant reduction of the competing ligand concentration. Decreasing reporter concentration (FIG. 25, top to bottom) does not significantly alter the f values but increases the fraction of bound reporter. On the other hand, the optimal f values for strongly binding competitors can be achieved at the concentrations of ˜1 μM and ˜0.1 μM by lowering protein concentrations 10- and 100-fold, respectively (FIG. 25, left to right), but the fraction of bound reporter is also significantly reduced. This reduction lessens the observed change of R₂ relaxation. Therefore, all concentrations should be considered to not only obtain an appropriate f value but also a significant fraction of bound reporter.

When 4-amidinopyridine was hyperpolarized at a concentration of 1.5 mM, signal enhancement values close to 100-fold could be achieved using 50% para-enriched H₂. After dilution and mixing with the non-hyperpolarized sample, a final sample concentration of ˜150 μM was achieved for the reporter ligand. As discussed, increasing the para-percentage to 99% and further modifications in the experimental setup would enable lowering the final concentration of 4-amidinopyridine to 20 μM or less, and the protein concentration to the sub-micromolar range. This in turn would allow to further lower the concentration of the competing ligand in accordance with the above discussion.

Compared to benzamidine, a widely reported ligand for trypsin, the chosen reporter ligand contains an additional N-atom in the aromatic ring. This change in structure is required, as benzamidine cannot be hyperpolarized by SABRE. At the same time, the change in the structure facilitates the use of the molecule as a reporter ligand by reducing its affinity for the protein. A ligand of low affinity is in fast exchange with the protein, which is a requirement for the competitive binding experiment. Without being bound by any theory, although drug candidates or other molecules of biological interest may not themselves be SABRE hyperpolarizable, the described method utilizes only a single weakly binding reporter ligand for characterizing the binding of any other ligand to the same site of the protein. The reporter ligand may be found by modifying a known ligand for the target protein as for 4-amidinopyridine vs. benzamidine employed here. Additionally, computational methods may be utilized to identify a weakly binding ligand in silico. Relevant methods include combining docking with molecular dynamics simulations and determination of free energies for the protein-ligand interaction.

### Example 12

The instant example provides for the dissociation constant of a ligand of interest can be determined with the measurement of R₂ relaxation under competitive binding. Thus, a single reporter ligand will allow the screening of a library of potential ligands to determine whether they bind to the protein, and to measure the binding affinity. This task is a common application of NMR in drug discovery. The ability to continuously produce SABRE hyperpolarization for a reporter ligand mixture, in combination with additional improvements of the injection device such as autosampling and possible complementary strategies including parallelized detection or immobilization of target proteins would enable true high-throughput screening using this method. The time required per sample may be reduced to close to the NMR scan time on the order of tens of seconds or less.

SABRE polarization enhances the signals of ¹H in the molecule to be detected by several orders of magnitude. In the experiments described here, the increased signal facilitated distinguishing these signals from the water peak even in spectra acquired from echoes with short echo time, and after additional water suppression at a water proton concentration that was up to 10⁵ times larger than the signals to be detected. In other applications, the signal enhancement from this hyperpolarization method could also be used to identify the molecule to be detected in the presence of other, abundant signals. It can become possible to measure biomolecular interactions in samples containing many different components, even without requiring purification. In such applications, the hyperpolarization can be used in a similar way as an isotope label would be applied with an isotope filtered conventional NMR experiment. However, the use of ¹H SABRE hyperpolarization does not require the synthesis of compounds incorporating ¹³C or ¹⁵N labels, which is often difficult or expensive. In addition to ¹H, SABRE can also be used to hyperpolarize other nuclei. The aforementioned ¹⁵N or ¹³C nuclei in molecules such as pyridine or pyruvate have been polarized using the SABRE-SHEATH method, which employs a magnetic shield to reduce the ambient field to the μT range during the polarization step. Additionally, ¹⁹F in heterocyclic rings can be hyperpolarized by the same method. ¹⁹F has an intrinsically high natural isotope abundance, and therefore does not require enrichment. Significant ¹⁹F signal enhancements of molecules such as 3-fluoropyridine, >100-fold, have been described. Fluorine atoms are abundant in drug molecules and drug lead compounds. Approximately 20% of commercial pharmaceuticals contain this nucleus, with many possessing fluorine-substituted nitrogen heterocyclic compounds. Without being bound by any theory, the abundance of such structural motifs could indicate the potential of using ¹⁹F SABRE hyperpolarization for investigating protein-ligand interactions. With ¹⁹F detection, NMR spectra are background-free, and thus do not require solvent subtraction techniques such as described in FIG. 15, which would further simplify the experiment.

Apart from detecting the interaction of small molecules with a protein, the method based on a small-molecule reporter ligand hyperpolarized by SABRE could be applicable to other biophysical studies. These include the characterization of enzymes, as well as the determination of macromolecular interactions, such as protein-protein or protein-nucleic acid interactions that cause the displacement of a ligand.

1. A method for measuring interactions between a ligand and a protein, the method comprising:
hyperpolarizing a ligand in a solvent using para-hydrogen to form a first solution;
transferring the first solution to a detector;
mixing the first solution with a protein solution, the protein solution having one or more ligands of interest therein; and
determining interactions of the hyperpolarized ligand with the one or more ligands of interest by observing a change in an NMR signal of the hyperpolarized ligand,
wherein the ligand includes one or more sites for hyperpolarization by parahydrogen, and one or more binding sites for interaction with the protein.

2. The method of claim 1, wherein the ligand is hyperpolarized by signal amplification by reversible exchange (SABRE) to transfer nuclear spin polarization from para-hydrogen.

3. The method of claim 2, wherein the nuclear spin polarization is transferred from para-hydrogen to molecules of interest.

4. The method of claim 1, wherein determining interactions of the hyperpolarized ligand is performed in the absence of superconducting magnets.

5. The method of claim 1, wherein determining interactions of the hyperpolarized ligand is performed in the absence of high field NMR.

6. The method of claim 1, wherein hyperpolarization of the ligand in the solvent is performed in an organic solvent.

7. The method of claim 6, wherein the hyperpolarization of the ligand further comprises using a hydrogenative catalyst for producing parahydrogen derived polarization.

8. The method of claim 6, wherein the organic solvent further comprises one or more of methanol, ethanol, chloroform, dichloromethane, or any combination thereof.

9. The method of claim 1, further comprising diluting the solvent to minimize a concentration of organic solvent therein.

10. The method of claim 9, wherein the solvent is diluted at a ratio approximately in a range of about 1:10 to about 1:100.

11. The method of claim 1, wherein transferring the first solution to the detector further comprises injecting the hyperpolarized molecule into an NMR spectrometer.

12. The method of claim 11, wherein the injecting is automated.

13. The method of claim 1, wherein observing a change in the NMR signal of the hyperpolarized ligand further comprises measuring a change in spin rate of the hydrogens in the ligand.

14. A method for creating a polarizable ligand for use in detecting the interaction of a protein with competitively binding ligands, the method comprising:
introducing a signal amplification by reversible exchange (SABRE) catalyst or a reaction site for a hydrogenative polarization transfer catalyst to a first ligand in a solvent to produce hyperpolarization of the first ligand; and
mixing hyperpolarized first ligand with a protein solution having a second ligand admixed therein to form a solution,
such that a signal of the first ligand in the presence of the second ligand differs from a signal of the first ligand in the absence of the second ligand.

15. The method of claim 14, wherein further comprising injecting the solution into an NMR spectrometer.

16. The method of claim 14, further comprising adjusting a concentration of one or more of the second ligand, the polarization transfer catalyst, or an exchange rate in the catalyst-ligand complex.

17. The method of claim 14, wherein introducing the transfer catalyst further comprises bubbling a para-enriched hydrogen gas into the organic solvent.

18. The method of claim 17, wherein the para-enriched hydrogen gas is delivered at a pressure of about 10 bar.

19. The method of claim 14, wherein a concentration of the second ligand in the protein solution is approximately in a range of about 10 micromolars to about 500 micromolars.

20. The method of claim 14, further comprising adjusting a concentration of the second ligand in the protein solution in response to expected binding affinities.
